(19) United States
(12) Patent Application Publication
(10) Pub. No.: US 2025/0093766 A1
(43) Pub. Date: Mar. 20, 2025

(54) TEMPLATE SUBSTRATE AND MANUFACTURING METHOD AND MANUFACTURING APPARATUS THEREOF, SEMICONDUCTOR SUBSTRATE AND MANUFACTURING METHOD AND MANUFACTURING APPARATUS THEREOF, SEMICONDUCTOR DEVICE, AND ELECTRONIC DEVICE

(71) Applicant: KYOCERA Corporation, Kyoto-shi, Kyoto (JP)

(72) Inventors: Takeshi KAMIKAWA, Kyoto-shi (JP); Yuta AOKI, Kyoto-shi (JP); Toshihiro KOBAYASHI, Kyoto-shi (JP)

(73) Assignee: KYOCERA Corporation, Kyoto-shi, Kyoto (JP)

(21) Appl. No.: 18/580,803

(22) PCT Filed: Jul. 8, 2022
(86) PCT No.: PCT/JP2022/027064

§ 371 Date: Jan. 19, 2024

(30) Foreign Application Priority Data
Jul. 21, 2021 (JP) 2021-120981

(51) Int. Cl. G03F 1/60; H01L 21/02; H01L 21/308

(52) U.S. Cl. CPC G03F 1/60; H01L 21/0254; H01L 21/02645; H01L 21/02647; H01L 21/3086

(57) ABSTRACT

A template substrate includes a main substrate containing silicon and including an edge, a mask located above the main substrate and including an opening portion, a seed portion located at the opening portion above the main substrate, and a protecting portion overlapping the edge when viewed from a side and containing a material different from gallium.

### TECHNICAL FIELD

The present disclosure relates to a template substrate and the like.

### BACKGROUND OF INVENTION

In order to manufacture semiconductor devices using GaN (gallium nitride), research has been conducted on a technique for forming GaN-based semiconductor elements. For example, Patent Document 1 discloses a technique for forming a GaN-based semiconductor layer on a GaN-based substrate or a heterogeneous substrate (for example, a silicon substrate or sapphire substrate) by using an ELO (epitaxial lateral overgrowth) method.

### CITATION LIST

### Patent Literature

Patent Document 1: JP 2012-114263 A

### SUMMARY

A template substrate according to an aspect of the present disclosure includes: a main substrate containing silicon and including a side surface; a mask located above the main substrate and including an opening portion; a seed portion located at the opening portion above the main substrate; and a protecting portion overlapping the side surface when viewed from a side and containing a material different from gallium.

### BRIEF DESCRIPTION OF THE DRAWINGS

FIG. 1 is a plan view illustrating a configuration of a template substrate in an embodiment of the present disclosure.

FIG. 2 is a cross-sectional view taken along an arrow line II-II in FIG. 1.

FIG. 3 is a cross-sectional view taken along an arrow line III-III in FIG. 1.

FIG. 4 is a cross-sectional view for explaining a semiconductor substrate in the embodiment of the present disclosure.

FIG. 5A is a partially enlarged view of a plan view illustrating a configuration of the semiconductor substrate in the embodiment of the present disclosure.

FIG. 5B is a cross-sectional view taken along an arrow line B-V in FIG. 5A.

FIG. 6 is a flowchart illustrating an example of a method for manufacturing the template substrate and the semiconductor substrate in the embodiment of the present disclosure.

FIG. 7 is a block diagram illustrating an example of a manufacturing apparatus in the embodiment of the present disclosure.

FIG. 8 is a flowchart illustrating an example of a method for manufacturing a semiconductor device in the embodiment of the present disclosure.

FIG. 9 is a plan view illustrating an example of isolation of an element portion.

FIG. 10 is a cross-sectional view illustrating an example of isolation and separation of an element portion.

FIG. 11 is a schematic view illustrating a configuration of an electronic device in the embodiment of the present disclosure.

FIG. 12 is a schematic view illustrating another configuration of the electronic device in the embodiment of the present disclosure.

FIG. 13A is a cross-sectional view illustrating a configuration of a template substrate in another embodiment of the present disclosure.

FIG. 13B is also a cross-sectional view illustrating a configuration of the template substrate in the other embodiment of the present disclosure.

FIG. 14 is a plan view illustrating a configuration of a template substrate in Example 1.

FIG. 15A is a cross-sectional view taken along an arrow line A-XV in FIG. 14.

FIG. 15B is a cross-sectional view taken along an arrow line B-XV in FIG. 14.

FIG. 16 is a plan view illustrating a configuration of a template substrate in Example 2.

FIG. 17A is a cross-sectional view taken along an arrow line A-XVII in FIG. 16.

FIG. 17B is a cross-sectional view taken along an arrow line B-XVII in FIG. 16.

FIG. 18 is a plan view illustrating a configuration of a template substrate in Example 3.

FIG. 19 is a cross-sectional view taken along an arrow line XIX-XIX in FIG. 18.

FIG. 20 is a cross-sectional view illustrating a configuration of a template substrate in Example 4.

FIG. 21 is a cross-sectional view illustrating another configuration of the template substrate in Example 4.

FIG. 22 is a plan view illustrating a configuration of a template substrate in Example 5.

FIG. 23 is a cross-sectional view taken along an arrow line XXIII-XXIII in FIG. 22.

FIG. 24 is a cross-sectional view for explaining a method for manufacturing the template substrate in Example 5.

FIG. 25 is a plan view illustrating a configuration of a template substrate in Example 6.

FIG. 26 is a cross-sectional view taken along an arrow line XXVI-XXVI in FIG. 25.

FIG. 27 is a plan view illustrating a configuration of a template substrate in Example 7.

FIG. 28 is a cross-sectional view taken along an arrow line XVIII-XVIII in FIG. 27.

FIG. 29 is a cross-sectional view illustrating a configuration of a template substrate in Example 8.

FIG. 30 is a cross-sectional view illustrating a configuration of a template substrate in Example 9.

FIG. 31 is a cross-sectional view illustrating a configuration of a template substrate in Example 10.

FIG. 32 is a cross-sectional view illustrating a configuration of a template substrate in Example 11.

FIG. 33 is a cross-sectional view illustrating another configuration of the template substrate in Example 11.

FIG. 34 is a cross-sectional view illustrating a configuration of a template substrate in Example 12.

### DESCRIPTION OF EMBODIMENTS

An embodiment will be described below with reference to the accompanying drawings. Note that the following description is for better understanding of the gist of the invention and does not limit the present disclosure unless otherwise specified. Unless otherwise specified in the present description, “from A to B” representing a numerical value range means “A or more and B or less”. Shapes and dimensions (length, width, and the like) of configurations illustrated in each of the drawings in the present application do not necessarily reflect actual shapes and dimensions, and are appropriately changed for clarification and simplification of the drawings.

In the following description, in order to facilitate understanding of a template substrate according to an aspect of the present disclosure, findings of the present disclosure will be schematically described first.

### Summary of Findings of Present Disclosure

A technique to grow a GaN-based semiconductor layer on, for example, a silicon substrate by using an ELO method has been known. In general, a commercially available wafer (hereinafter referred to as a commercially available wafer CW) is not sold as a product for use in forming a GaN-based semiconductor layer by using the ELO method. However, by using the commercially available wafer CW as a substrate and forming a mask on the substrate, a GaN-based semiconductor can be formed on the substrate by using the ELO method.

The inventors of the present invention have obtained the following findings during studies on a technique for producing a GaN-based semiconductor layer by the ELO method. That is, the inventors have found that when the GaN-based semiconductor layer is formed using the substrate as described above, melt-back etching occurs in an end surface (side surface) portion of the substrate, and a damaged portion may possibly be generated in part of the substrate. Hereinafter, in the present description, for convenience of description, melt-back etching that occurs in an end surface (side surface) portion of an underlying substrate or a template substrate is referred to as melt-back etching SMB. When part of the substrate is damaged by the occurrence of the melt-back etching SMB, an effective area of the GaN-based semiconductor layer that can be used for device formation may decrease (that is, the device yield may be lowered).

The inventors of the present invention have conducted intensive studies on a technique capable of reducing the occurrence of the melt-back etching SMB under film formation conditions of a GaN-based semiconductor layer by the ELO method, and have achieved a template substrate according to an aspect of the present disclosure.

### Template Substrate

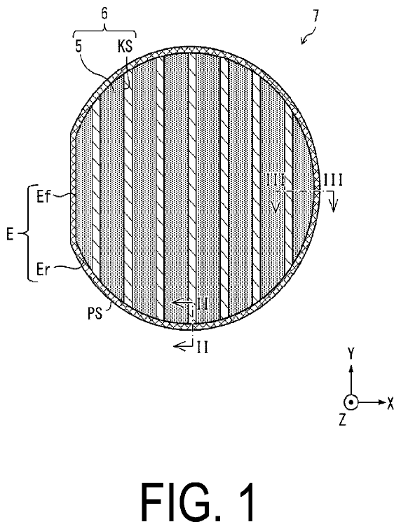

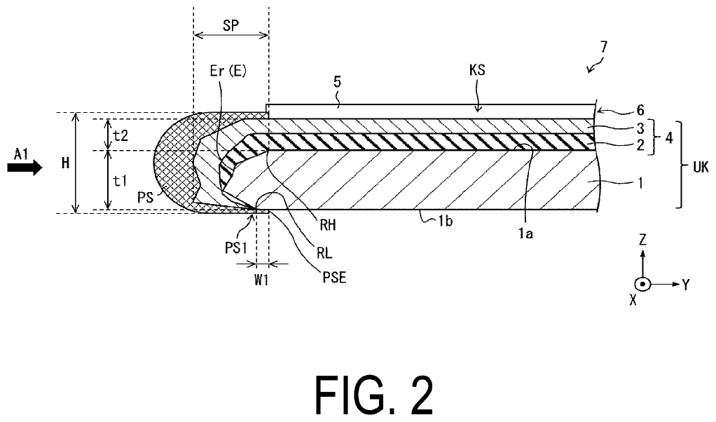

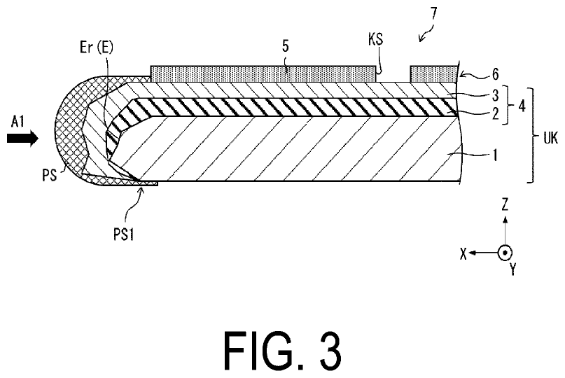

A template substrate 7 in the embodiment of the present disclosure will be described below with reference to FIGS. 1, 2, and 3. FIG. 1 is a plan view illustrating a configuration of the template substrate 7. FIG. 2 is a cross-sectional view taken along an arrow line II-II in FIG. 1. FIG. 3 is a cross-sectional view taken along an arrow line III-III in FIG. 1.

As illustrated in FIGS. 1, 2, and 3, the template substrate 7 in the present embodiment includes a main substrate 1 containing silicon and having an edge E (end surface, side surface), an underlying portion 4 located above the main substrate 1, a mask 6 located above the main substrate 1 and having an opening portion KS, and a protecting portion PS overlapping the edge E when viewed from a side. In the template substrate 7, a buffer portion 2 and a seed portion 3 may be provided as the underlying portion 4 in that order from the main substrate 1 side. The seed portion 3 may be located at the opening portion KS above the main substrate 1. The protecting portion PS may contain a material different from gallium (Ga).

The underlying portion 4, the buffer portion 2, the seed portion 3, and the mask 6 typically are layers. Therefore, the underlying portion 4 may also be referred to as an underlying layer 4. The buffer portion 2 may be referred to as a buffer layer 2, the seed portion 3 may be referred to as a seed layer 3, and the mask 6 may be referred to as a mask layer 6. The terms “underlying layer 4”, “buffer layer 2”, “seed layer 3”, and “mask layer 6” are used in the following description, but these elements are not necessarily limited to a layer form.

The main substrate 1 has the edge E (side surface, end surface) having a non-uniform shape (angular shape) in a cross-sectional view. The edge E mentioned above may be formed by chamfering in a manufacturing process of the main substrate 1. In the template substrate 7 of the present embodiment, the edge E of the main substrate 1 includes a curved surface portion Er and a flat surface portion Ef, but is not limited thereto. The edge E may be constituted by only a curved surface or a flat surface. The main substrate 1 may have the edge E without being chamfered.

One plate surface (upper surface) of two plate surfaces of the main substrate 1 is referred to as a main surface 1a, and the other plate surface thereof is referred to as a lower surface 1b. The template substrate 7 may include a plurality of layers laminated on the main surface 1a. In the present description, a laminate direction in which a plurality of layers are laminated on the main surface 1a is referred to as an “upward direction”, and viewing a substrate-like subject such as the template substrate 7 with a line of sight parallel to the normal line of the main surface 1a, for example, is referred to as a “plan view” in some cases. As for a substrate-like subject such as the template substrate 7, the main surface 1a is considered to be virtually a flat surface and the side surface of the subject is considered to be a flat surface including the normal direction of the main surface 1a in an in-plane direction, and viewing the subject in the normal direction of the side surface of the subject (virtual flat surface) is referred to as a “side view” in some cases. For example, the side view of the template substrate 7 means that the template substrate 7 is viewed in the direction of an arrow Al depicted in FIGS. 2 and 3. A situation in which two constituent elements overlap each other in a side view may also be a situation in which at least part of one constituent element overlaps the other constituent element when viewed in a direction perpendicular to the substrate normal line of the template substrate 7 (including a transparent view). The two constituent elements may be in contact with each other or may be spaced apart without contact. A situation in which two constituent elements overlap each other in a plan view refers to a situation in which at least part of one constituent element overlaps the other constituent element when viewed in the normal direction of the main substrate 1 (including a transparent view). The two constituent elements may overlap each other while being spaced apart (for example, in an up-down direction).

The template substrate 7 may include the buffer layer 2 and the seed layer 3, which overlap the entirety of the main surface 1a of the main substrate 1 in a plan view. Hereinafter, the main substrate 1 and the underlying layer 4 may be collectively referred to as an underlying substrate UK. The mask layer 6 formed on the underlying substrate UK includes a plurality of mask portions 5 and a plurality of opening portions KS. The mask portion 5 and the opening portion KS each have a longitudinal shape in which a first direction (X direction) is a width direction and a second direction (Y direction) is a longitudinal direction. The opening portion KS may have a tapered shape (a shape that becomes narrower downward). The mask layer 6 may have a shape in which both ends in the longitudinal direction of the opening portion KS are open, that is, a shape in which the mask portion 5 does not exist at both the ends in the longitudinal direction, and may be formed on the underlying substrate UK in a so-called edge-to-edge shape. The mask layer 6 may be a mask pattern including the mask portion 5 and the opening portion KS. The opening portion KS is a region where the mask portion 5 does not exist, and the opening portion KS is allowed not to be surrounded by the mask portion 5.

For example, when a silicon substrate is used for the main substrate 1 and a GaN-based semiconductor is used for the seed layer 3, both constituent elements (the main substrate and the seed layer) may melt together. To deal with this, for example, by providing the buffer layer 2 including an AlN layer and/or a SiC (silicon carbide) layer, the possibility that the main substrate 1 and the seed layer 3 melt together may be lowered. When the main substrate 1 unlikely to melt together with the seed layer 3 is used, a configuration may be employed in which the buffer layer 2 is not provided. When the seed layer 3 having low reactivity with the main substrate 1 is used, a configuration may be employed in which the buffer layer 2 is not provided. Note that the present disclosure is not limited to the configuration in which the seed layer 3 overlaps the entire mask portion 5 as illustrated in FIGS. 2 and 3. Since the seed layer 3 only needs to be exposed from the opening portion KS, the seed layer 3 may be locally formed in such a manner as not to overlap part of or the entirety of the mask portion 5.

The mask layer 6 may be formed as follows, for example. That is, a SiO₂ film is formed on the entire surface of the underlying substrate UK by sputtering, and then wet etching is performed while partially protecting the film with a resist. By part of the SiO₂ film being removed, the mask portion 5 and the opening portion KS are formed. In general, the side surface of the underlying substrate UK is not covered with the SiO₂ film. This is because (i) the SiO₂ film does not sufficiently extend to the side surface of the underlying substrate UK by sputtering, (ii) the SiO₂ film is removed by etching because the resist is not sufficiently applied to the side surface of the underlying substrate UK unless the resist is intentionally applied to the side surface thereof, and the like.

The template substrate 7 may be used for the formation of a semiconductor part, for example, for the film formation of a GaN-based semiconductor part by the ELO method. The GaN-based semiconductor is a semiconductor including gallium atoms (Ga) and nitrogen atoms (N), and examples thereof include GaN, AlGaN, AlGaInN, and InGaN. In the ELO method, for example, the seed layer 3 including a GaN-based semiconductor is used, an inorganic compound film such as a SiO₂ film is used for the mask layer 6, and a GaN-based semiconductor part can be laterally grown on the mask portion 5. The thickness direction (Z direction) of the GaN-based semiconductor part can be the <0001> direction (c-axis direction) of a GaN-based crystal, the width direction (X direction) of the opening portion KS can be the <11-20> direction (a-axis direction) of the GaN-based crystal, and the longitudinal direction (Y direction) of the opening portion KS can be the <1-100> direction (m-axis direction) of the GaN-based crystal. The GaN-based semiconductor part typically is a layer. Therefore, the GaN-based semiconductor part may also be referred to as a GaN-based semiconductor layer. The term “GaN-based semiconductor layer” will be used in the following description, but the GaN-based semiconductor layer is not necessarily limited to a layer form. A layer formed by the ELO method may be referred to as an ELO semiconductor layer.

When the ELO semiconductor layer is formed, the melt-back etching SMB may occur as described above. The reason for this is not clear, but the following mechanism may be considered.

The buffer layer 2 is formed under the conditions that do not obstruct the extension of a raw material for film formation to the side surface (covering the side surface) of the main substrate 1. However, the layer is thin to be approximately 100 nm in thickness, and is difficult to be formed to cover the side surface of the main substrate 1 by nature. Accordingly, the thickness of the buffer layer 2 is considered to be non-uniform at the side surface part of the template substrate 7 due to the non-uniformity of the side surface shape of the main substrate 1, the thinness of the buffer layer 2, and the like. As a result, a portion may be present where the main substrate 1 and the seed layer 3 are not sufficiently isolated from each other by the buffer layer 2. In other words, the side surface part of the template substrate 7 may be considered to have a minute region in which the thickness of the buffer layer 2 is too thin, the buffer layer 2 has a crack, or the buffer layer 2 does not completely (effectively) protect the main substrate 1. Hereinafter, in the present description, a portion (the above-described minute region) which may be a generation starting point of the melt-back etching SMB is referred to as an “abnormal portion DP”.

Here, when the thickness of the buffer layer 2 at the side surface portion of the template substrate 7 is increased, the thickness of the buffer layer 2 on the main surface 1a of the main substrate 1 is also increased at the same time, and in this case, the original function of the buffer layer 2 may be impaired. Specifically, cracking may occur in the buffer layer 2 due to internal stress of the buffer layer 2 and stress caused by differences in thermal expansion coefficient and lattice constant between the buffer layer 2 and the main substrate 1. As a result, melt-back etching of the main substrate 1 and the seed layer 3 may occur through the cracking. Therefore, the thickness of the buffer layer 2 cannot be freely increased.

The film formation conditions when forming the ELO semiconductor layer have an influence on the state of occurrence of the melt-back etching SMB. For example, when the film formation temperature is made to exceed 1050° C. in order to secure the lateral film formation rate, the melt-back etching SMB is likely to occur. When the film formation time is relatively long, the surface area of a region where the melt-back etching SMB occurs increases.

The template substrate 7 according to an aspect of the present disclosure can be configured to include the protecting portion PS formed along the outer periphery of the underlying substrate UK. The protecting portion PS covers the side surface (end surface) of the underlying substrate UK and overlaps the edge E of the main substrate 1 when viewed from a side. The protecting portion PS includes, for example, a nitride film containing silicon, an oxide film containing silicon, or an oxynitride film containing silicon. The protecting portion PS may typically include a silicon nitride (SiN) film or a SiO₂ film.

The protecting portion PS may include a material different from gallium (Ga). More specifically, the protecting portion PS may include a material different from a simple substance of Ga and a Ga compound (hereinafter referred to as a non-Ga-based material for convenience of description). Examples of the non-Ga-based material included in the protecting portion PS include silicon nitride, silicon oxide, silicon oxynitride, and aluminum silicon oxide. The protecting portion PS may include a plurality of types of the non-Ga-based materials.

The protecting portion PS may contain the non-Ga-based material in a larger amount than that of Ga. More specifically, the content of the non-Ga-based material may be larger than the sum of the content of the simple substance of Ga and the content of the Ga compound. When the plurality of types of non-Ga-based materials are included, the content of the non-Ga-based materials in the protecting portion PS refers to the total content of all the types of non-Ga-based materials included in the protecting portion PS.

The protecting portion PS may be an inorganic insulating film or an inorganic insulating layer which does not contain Ga or does not substantially contain Ga. The phrase “does not substantially contain Ga” means that Ga may be mixed into the protecting portion PS as an unavoidable impurity, or that Ga mixed into the protecting portion PS by the diffusion of atoms from the seed layer 3 may be contained. The protecting portion PS may have a function of reducing the occurrence of the melt-back etching SMB in the side surface part of the template substrate 7, and may contain Ga in an allowable concentration range. For example, the protecting portion PS may contain Ga in a molar ratio of 1% or less in the component composition.

The protecting portion PS may be formed using, for example, a CVD (chemical vapor deposition) method or a plasma CVD method, or may be formed by other methods. Hereinafter, the template substrate 7, in which the protecting portion PS is formed using the plasma CVD method, will be described.

As illustrated in FIG. 2, the distance from the lowest position to the highest position of the protecting portion PS in the thickness direction (Z direction) of the template substrate 7 is defined as a height H, the plate thickness of the main substrate 1 is defined as t1, and the layer thickness of the underlying layer 4 is defined as t2. The protecting portion PS may have the height H greater than the plate thickness t1, or may have the height H greater than the sum of the plate thickness t1 and the layer thickness t2. The height H may be in a range from 200 μm to 1200 μm, or may be in a range from 300 μm to 1100 μm, for example.

In the present description, a ridge line (intersection point in a cross-sectional view) where the edge E of the main substrate 1 and the main surface 1a intersect each other is referred to as RH, and a ridge line (intersection point in a cross-sectional view) where the edge E of the main substrate 1 and the lower surface 1b intersect each other is referred to as RL. A side surface part of the underlying substrate UK located on the outer peripheral side relative to the ridge line RH (located on the side far from the center portion) is referred to as a side surface portion SP of the underlying substrate UK. In other words, the side surface portion SP of the underlying substrate UK is a portion including the main substrate 1, the buffer layer 2, and the seed layer 3 located on the outer side relative to the main surface 1a in an XY plane (in plan view).

The protecting portion PS may be in contact with the seed layer 3 in the side surface portion SP of the underlying substrate UK, or may cover the entire surface of the seed layer 3. The protecting portion PS may cover the side surface portion SP of the underlying substrate UK from the position of the lower surface 1b (in other words, the position of the ridge line RL) to the position of the main surface 1a (in other words, the position of the ridge line RH) in the Z direction. In this case, the protecting portion PS overlaps the entire edge E when viewed from a side. The protecting portion PS may cover the side surface portion SP of the underlying substrate UK from the position of the lower surface 1b beyond the position of the main surface 1a of the seed layer 3 (in other words, the position of the ridge line RH) in the Z direction. In this case, the protecting portion PS may cover the side surface portion SP so that the seed layer 3 is not exposed in the side surface portion SP. Part of the side surface portion SP and the mask portion 5 may be in contact with each other. In the present description, the expression that two different members are “in contact with each other” not only means that they are in direct contact with each other, but also means that they may be in indirect contact with each other via any other thin layer (which has a thickness of 2 μm or less, and may be constituted of a single layer or multiple layers, for example).

The template substrate 7 includes the protecting portion PS. By using the template substrate 7, when an ELO semiconductor layer is formed by the ELO method, Ga derived from a Ga raw material and supplied is blocked from reaching the main substrate 1. Thus, the possibility that the Ga derived from the Ga raw material and supplied reacts with the main substrate 1 via an abnormal portion DP may be lowered.

For example, in the abnormal portion DP, the seed layer 3 and the main substrate 1 may react with each other due to the absence of the buffer layer 2 or the thickness of the buffer layer 2 being thin. When the thickness of the buffer layer 2 is thin, Ga may pass through the buffer layer 2. In the template substrate 7, even if a reaction occurs in the abnormal portion DP, since no Ga is newly supplied to the reaction portion, the reaction can be limited to a local reaction between the seed layer 3 and the main substrate 1 in the abnormal portion DP.

Alternatively, in the template substrate 7, since Ga is not supplied to the abnormal portion DP from the outside, the possibility of the occurrence of the above-discussed reaction itself can be lowered. As a result, the possibility of the occurrence of the melt-back etching SMB may be lowered, and even if the melt-back etching SMB occurs, the surface area of the region where the melt-back etching SMB occurs may be reduced.

In the protecting portion PS, the thickness of a portion where the distance between the surface of the protecting portion PS and the surface of the seed layer 3 is shortest, in other words, the thickness of a portion of the protecting portion PS closest to the surface of the seed layer 3 (the thinnest portion) may be 100 nm or more. This makes it possible to effectively lower the possibility that Ga is supplied to the abnormal portion DP.

The lowest position of the protecting portion PS in the Z direction may be lower than the position of the lower surface 1b (in other words, the position of the ridge line RL); in this case, the protecting portion PS may be in contact with the lower surface 1b of the main substrate 1. The protecting portion PS may cover at least part of the lower surface 1b while including the ridge line RL. In other words, the protecting portion PS may overlap part of the lower surface 1b when viewed with a line of sight parallel to the normal line of the lower surface 1b. Hereinafter, a portion of the protecting portion PS covering the bottom side (lower surface 1b side) of the template substrate 7 may be referred to as a bottom side protecting portion PS1. The bottom side protecting portion PS1 may be part of the protecting portion PS.

In the template substrate 7, the buffer layer 2 and the seed layer 3 may slightly extend to the lower surface 1b. For example, in the cross-sectional view as illustrated in FIG. 2, the buffer layer 2 and the seed layer 3 may cover part of the lower surface 1b, and end portions of the buffer layer 2 and the seed layer 3 on the outer peripheral side may be located at a position distanced about several μm from the ridge line RL in the Y direction.

In the cross-sectional view as illustrated in FIG. 2, an end portion of the bottom side protecting portion PS1 on the center side of the template substrate 7 is referred to as a PSE. In the cross-sectional view as illustrated in FIG. 2, the distance between the position of the end portion PSE and the position closest to the center side of the template substrate 7 in the Y direction among the position of the ridge line RL, the position of the end portion of the buffer layer 2, and the position of the end portion of the seed layer 3 at the bottom side of the template substrate 7 is defined as W1. In the template substrate 7, the distance W1 in the bottom side protecting portion PS1 may be, for example, 1 μm or more; in this case, the possibility of the occurrence of the melt-back etching SMB caused by the Ga raw material gas coming to the lower surface 1b side may be effectively lowered. As a result, the possibility of the occurrence of the melt-back etching SMB may be further lowered. In the bottom side protecting portion PS1, the distance W1 may be, for example, in a range from 1 μm to 5000 μm. The above-discussed bottom side protecting portion PS1 can be formed by forming the protecting portion PS by using, for example, the plasma CVD method.

The protecting portion PS can be provided outside the side surface of the main substrate 1 in order not to expose the main substrate 1 to the side surface of the template substrate 7. The material of the protecting portion PS may be a gallium-free semiconductor such as AlN or SiC, or may be an amorphous material such as SiNx. A nitride semiconductor (for example, a GaN-based semiconductor) may be located between the side surface of the main substrate 1 and the protecting portion PS. The side surface of the main substrate 1 and the protecting portion PS may be in contact with each other. The protecting portion PS may have a shape extending from the upper side to the side of the main substrate 1. The protecting portion PS may be formed in the same layer as the mask portion 5 or formed in a layer above the mask portion 5. A thermal oxide film of the main substrate 1 (for example, a Si substrate) may be used as the protecting portion PS. The distance between the opening portion KS having a longitudinal shape and the side surface of the template substrate 7 may be larger than the width of the opening portion KS. The distance between the seed layer 3 and the side surface of the template substrate 7 may be larger than the width of the opening portion K.

### Semiconductor Substrate

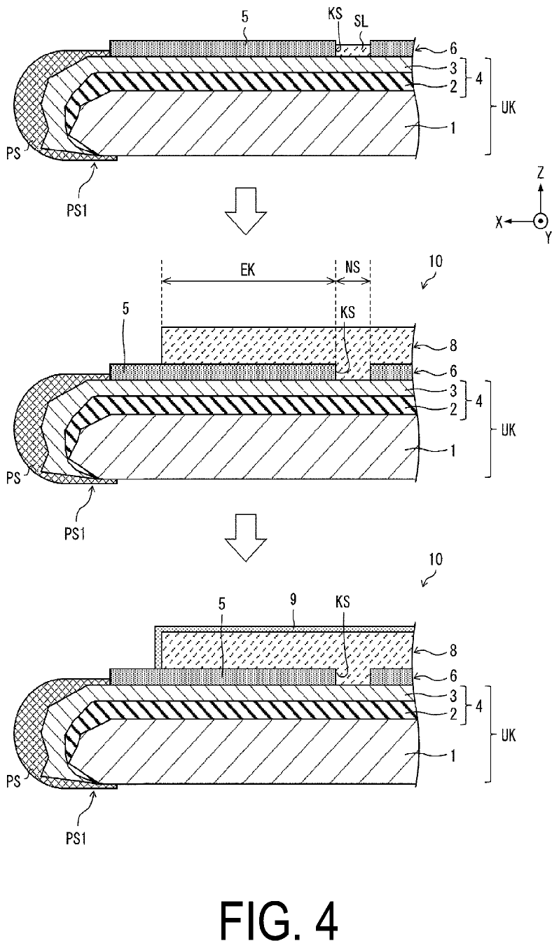

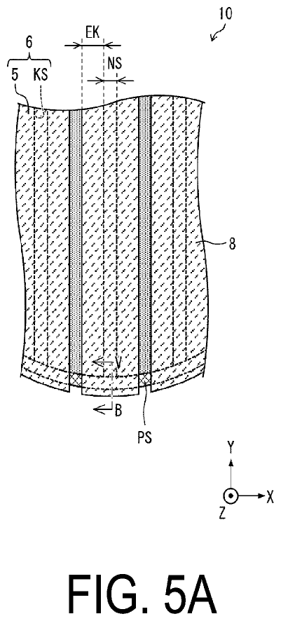

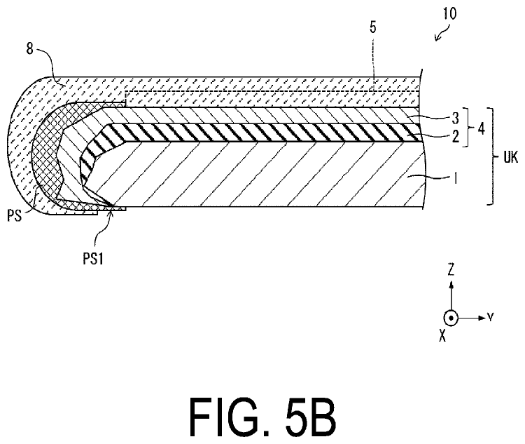

A semiconductor substrate 10 in the embodiment of the present disclosure will be described below with reference to FIGS. 4, 5A, and 5B. FIG. 4 is a cross-sectional view for explaining the semiconductor substrate 10 in the present embodiment. FIG. 4 illustrates a cross section corresponding to FIG. 3 and also illustrates an example of lateral growth.

As illustrated in FIG. 4, in a step of forming an ELO semiconductor layer on the template substrate 7 by the ELO method, first, an initial growth layer SL is formed starting from the seed layer 3 exposed in the opening portion KS. The initial growth layer SL is further grown and laterally grown, thereby forming an ELO semiconductor part 8. The ELO semiconductor part 8 includes, for example, a GaN-based semiconductor. In the semiconductor substrate 10, a functional portion 9 may be formed in a layer above the ELO semiconductor part 8. The functional portion 9 may be a single-layer body or a multiple-layer body. The functional portion 9 may have at least one selected from the group consisting of a function as a constituent element of a semiconductor device, a light-emitting function, a function of protection against external force, a function of protection against static electricity, a protection function of suppressing the entry of foreign matter such as water and oxygen, a function of protection against an etchant or the like, an optical function, and a sensing function.

The ELO semiconductor part 8 and the functional portion 9 typically are layers. Therefore, the ELO semiconductor part 8 may also be referred to as an ELO semiconductor layer 8, and the functional portion 9 may also be referred to as a functional layer 9. The terms “ELO semiconductor layer 8” and “functional layer 9” are used in the following description, but none of the ELO semiconductor layer 8 and the functional layer 9 are necessarily limited to layers.

The ELO semiconductor layer 8 includes an effective portion EK overlapping the mask portion 5 in a plan view and having a relatively small number of threading dislocations, and a non-effective portion NS overlapping the opening portion KS in the plan view and having a relatively large number of threading dislocations. When the functional layer 9 includes an active layer (for example, a layer in which electrons and holes are combined) above the ELO semiconductor layer 8, the functional layer 9 on the effective portion EK (in other words, at a position overlapping the effective portion EK in the plan view) can be formed to include the active layer having few defects and having high crystallinity. A device in which the active layer functions can be formed by forming a current injection region in the effective portion EK. Thus, for example, a device having high light emission efficiency may be produced.

The effective portion EK can be configured such that a non-threading dislocation density in a cross section parallel to the <0001> direction is greater than a threading dislocation density in the upper surface. The threading dislocation is a dislocation (defect) extending from the lower surface or inside of the ELO semiconductor layer 8 to the surface or surface layer thereof along the thickness direction (Z direction) of the ELO semiconductor layer 8. The threading dislocation may be observed by performing CL (cathode luminescence) measurement on the surface (parallel to a c-plane) of the ELO semiconductor layer 8. The non-threading dislocation is a dislocation measured by CL in a cross section taken along a plane parallel to the thickness direction, and is mainly a basal plane (c-plane) dislocation.

FIG. 5A is a partially enlarged view of a plan view illustrating the configuration of the semiconductor substrate 10. FIG. 5B is a cross-sectional view taken along an arrow line B-V in FIG. 5A. FIGS. 5A and 5B illustrate the semiconductor substrate 10 before the functional layer 9 is formed.

As illustrated in FIGS. 5A and 5B, when the template substrate 7 having an edge-to-edge shape is used in the semiconductor substrate 10, the ELO semiconductor layer 8 grown from the opening portion KS as a starting point by the ELO method can be formed to extend to the side of the semiconductor substrate 10. This is because the ELO semiconductor layer 8 also grows in the Y direction (the m-axis direction of the GaN-based crystal) at a slower growth rate than that in the X direction. In particular, when the film formation is performed under such conditions that allow the width of the effective portion EK to be widened, the ELO semiconductor layer 8 is likely to extend to the side of the semiconductor substrate 10. Even in such a case, since the semiconductor substrate 10 includes the protecting portion PS, the possibility of the occurrence of the melt-back etching SMB under the film formation conditions of the ELO semiconductor layer 8 may be effectively lowered. This makes it possible to increase the effective area of the effective portion EK in the semiconductor substrate 10. As a result, the yield of the devices produced by using the semiconductor substrate 10 may be improved.

The semiconductor substrate 10 may be provided with the protecting portion PS including the bottom side protecting portion PS1. In this case, even if the ELO semiconductor layer 8 is formed to extend to the bottom side of the semiconductor substrate 10, the Ga raw material gas is supplied, or the like, the possibility that Ga contacts the main substrate 1 may be lowered. Thus, the possibility of the occurrence of the melt-back etching SMB may be effectively lowered.

Although not illustrated, the ELO semiconductor layer 8 in the semiconductor substrate 10 may be formed in such a manner that semiconductor films laterally grown in the opposite directions from adjacent opening portions KS meet each other, and the ELO semiconductor layer 8 may be configured to include no edge on the mask portion 5 (association type). The semiconductor substrate 10 may include the functional layer 9 above the association type ELO semiconductor layer 8.

### Manufacture of Template Substrate and Semiconductor Substrate

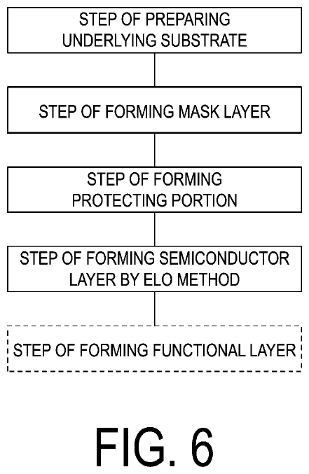

FIG. 6 is a flowchart illustrating an example of a method for manufacturing the semiconductor substrate 10 in the present embodiment. The flowchart illustrated in FIG. 6 can also include a method for manufacturing the template substrate 7.

As illustrated in FIG. 6, in the example of the method for manufacturing the template substrate 7 and the semiconductor substrate 10, the underlying substrate UK is prepared first. The underlying substrate UK may be produced by forming the underlying layer 4 on the main substrate 1. Subsequently, after a step of forming the mask layer 6 on the underlying substrate UK, a step of forming the protecting portion PS is further performed to produce the template substrate 7. The mask layer 6 may be formed after the protecting portion PS is formed. Alternatively, for example, when the mask layer 6 includes the protecting portion PS (see Example 1 and the like described later), the step of forming the mask layer 6 may include the step of forming the protecting portion PS. Subsequently, a step of forming the ELO semiconductor layer 8 on the template substrate 7 is performed using the ELO method. After the step of forming the ELO semiconductor layer 8, a step of forming the functional layer 9 can be performed as necessary.

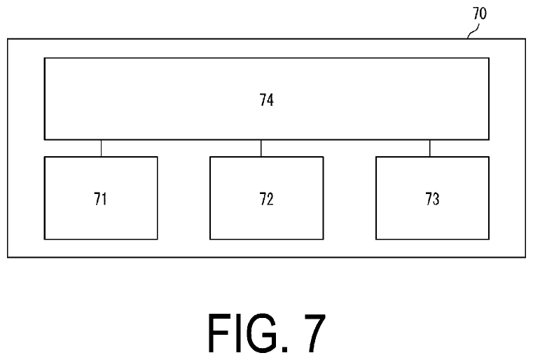

FIG. 7 is a block diagram illustrating an example of a manufacturing apparatus 70 in the present embodiment. As illustrated in FIG. 7, the manufacturing apparatus 70 includes a mask layer forming unit 71 configured to form the mask layer 6 on the underlying substrate UK, a protecting portion forming unit 72 configured to form the protecting portion PS, and a semiconductor layer forming unit 73 configured to form the ELO semiconductor layer 8 on the template substrate 7. The manufacturing apparatus 70 further includes a controller 74 configured to control the mask layer forming unit 71, the protecting portion forming unit 72, and the semiconductor layer forming unit 73.

The mask layer forming unit 71 may include one or a plurality of devices to perform various processes for forming the mask layer 6 on the underlying substrate UK, and a known device may be applicable as the device mentioned above. The protecting portion forming unit 72 may have a configuration in which a plurality of known devices are combined to make it possible to form the protecting portion PS. The protecting portion forming unit 72 may include a plasma CVD device. The semiconductor layer forming unit 73 forms the ELO semiconductor layer 8 (see FIG. 4 and the like) including the GaN-based semiconductor by the ELO method in such a manner that the ELO semiconductor layer 8 is in contact with the seed layer 3 and the mask portion 5. The semiconductor layer forming unit 73 may include an MOCVD (metal-organic CVD) device. The manufacturing apparatus 70 may be configured to form the functional layer 9, or may be configured to form the underlying layer 4 on the main substrate 1.

The controller 74 may include a processor and a memory. The controller 74 may be configured to control the mask layer forming unit 71, the protecting portion forming unit 72, and the semiconductor layer forming unit 73 by executing a program stored in, for example, a built-in memory, a communicable communication apparatus, or an accessible network. The program and a recording medium or the like in which the program is stored are also included in the present embodiment.

### Manufacturing Semiconductor Device

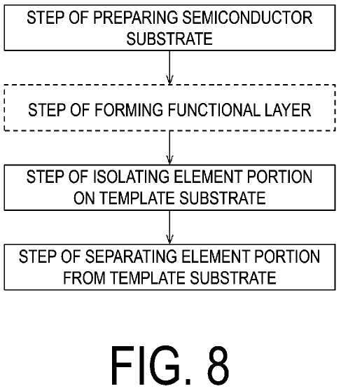

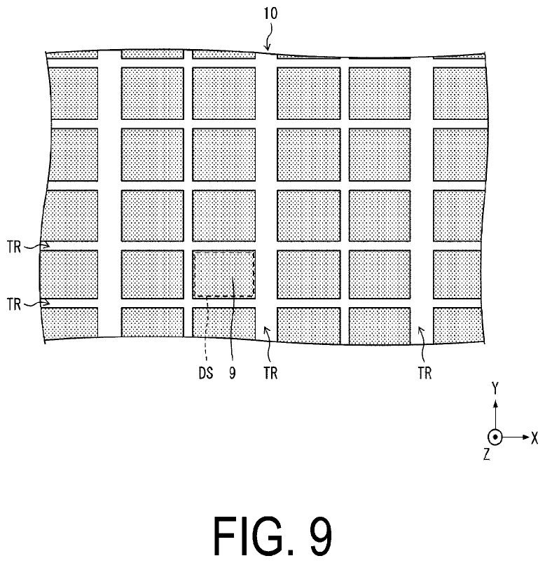

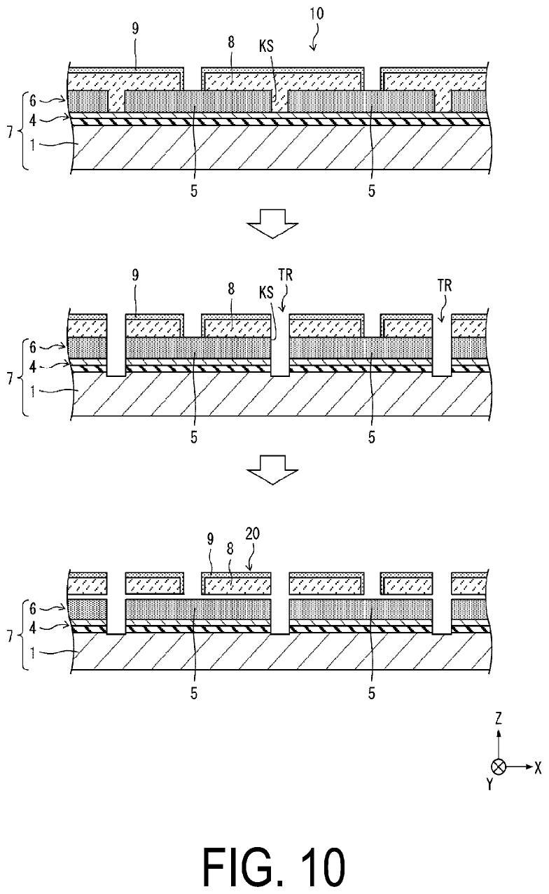

FIG. 8 is a flowchart illustrating an example of a method for manufacturing a semiconductor device in the present embodiment. FIG. 9 is a plan view illustrating an example of isolation of an element portion. FIG. 10 is a cross-sectional view illustrating an example of isolation and separation of an element portion.

As illustrated in FIG. 8, in the example of the method for manufacturing a semiconductor device, after a step of preparing the semiconductor substrate 10, a step of forming the functional layer 9 on the ELO semiconductor layer 8 is performed as necessary. Subsequently, a step of forming a plurality of trenches TR (isolation trenches) on the semiconductor substrate 10 to isolate an element portion DS (including the effective portion EK of the ELO semiconductor layer 8 and the functional layer 9) is performed as illustrated in FIGS. 9 and 10. The element portion DS is connected to the substrate (underlying substrate UK) at the opening portion KS, and a back surface of the element portion DS and the mask portion 5 are weakly bonded to each other by Van der Waals' force at the effective portion EK. Therefore, by forming the trench TR (isolation trench) over the opening portion KS, forming the trench TR such that the trench bottom portion is lower than the surface height of the mask portion 5, and setting the opening width of the trench TR to be equal to or larger than the width of the opening portion KS, the element portion DS can be easily peeled from the substrate. The trench TR passes through the functional layer 9 and the ELO semiconductor layer 8. The mask portion 5 and the main substrate 1 may be exposed in the trench TR. Subsequently, a step of separating the element portion DS from the template substrate 7 to form a semiconductor device is performed. The step of preparing the semiconductor substrate 10 in FIG. 8 may include the steps of the method for manufacturing the template substrate 7 and the semiconductor substrate 10 illustrated in FIG. 6.

The template substrate 7 may include the underlying substrate UK and a mask pattern on the underlying substrate UK. The template substrate 7 may include a growth suppression region (for example, a region that suppresses crystal growth in the Z direction) corresponding to the mask portion 5 and a seed region corresponding to the opening portion KS. For example, the growth suppression region and the seed region may be formed on the underlying substrate UK, and the ELO semiconductor layer 8 may be formed on the growth suppression region and the seed region by using the ELO method.

### Semiconductor Device

As illustrated in FIG. 10, by separating the element portion DS from the template substrate 7, a semiconductor device 20 (including the ELO semiconductor layer 8) can be formed. For example, after the element portion DS is separated from the template substrate 7, an n-electrode or the like may be formed on the back surface of the separated element portion DS. Specific examples of the semiconductor device 20 include a light emitting diode (LED), a semiconductor laser, a Schottky diode, a photodiode, and transistors (including a power transistor and a high electron mobility transistor).

### Electronic Device

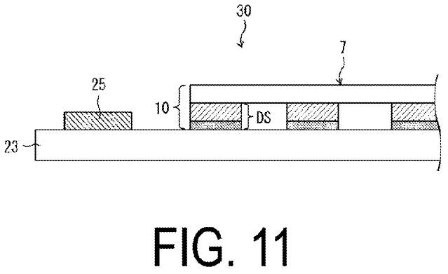

FIG. 11 is a schematic view illustrating a configuration of an electronic device according to the present embodiment. An electronic device 30 in FIG. 11 includes the semiconductor substrate 10 (configured to function as a semiconductor device with the template substrate 7 included therein, for example, in a case where the template substrate 7 is light-transmissive), a drive substrate 23, on which the semiconductor substrate 10 is mounted, and a control circuit 25 configured to control the drive substrate 23.

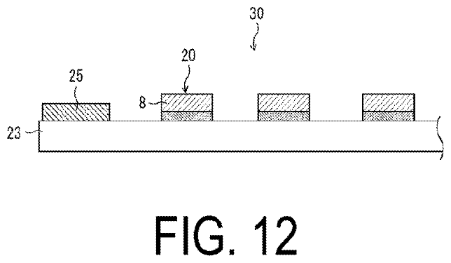

FIG. 12 is a schematic view illustrating another configuration of the electronic device according to the present embodiment. The electronic device 30 in FIG. 12 includes the semiconductor device 20 including at least the effective portion EK, the drive substrate 23, on which the semiconductor device 20 is mounted, and the control circuit 25 configured to control the drive substrate 23.

Examples of the electronic device 30 include display devices, laser emitting devices (including a Fabry-Perot type and a surface emitting type), lighting devices, communication apparatuses, information processing devices, sensing devices, and electrical power control devices.

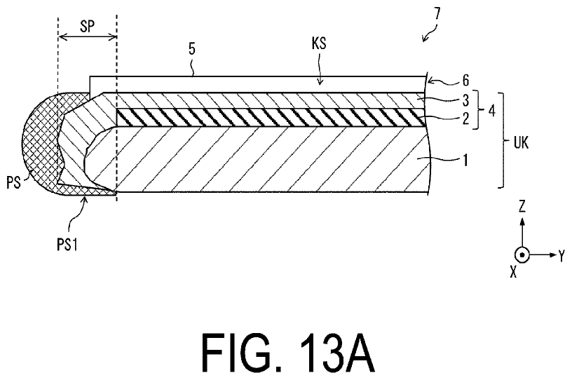

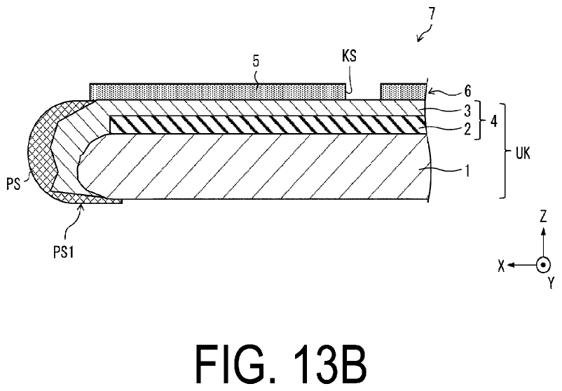

### Other Configurations

[1] FIG. 13A and FIG. 13B are cross-sectional views illustrating the configuration of the template substrate 7 in another embodiment of the present disclosure. FIG. 13A illustrates a cross section corresponding to FIG. 2, and FIG. 13B illustrates a cross section corresponding to FIG. 3.

As illustrated in FIGS. 13A and 13B, the template substrate 7 is allowed not to include the buffer layer 2 in the side surface portion SP of the underlying substrate UK. In this case as well, in the same or similar manner as discussed above, the template substrate 7, by including the protecting portion PS, can lower the possibility that Ga derived from a Ga raw material and supplied reaches the main substrate 1 when forming the ELO semiconductor layer 8 by the ELO method. As a result, the possibility of the occurrence of the melt-back etching SMB may be lowered, and even if the melt-back etching SMB occurs, the surface area of the region where the melt-back etching SMB occurs may be reduced.

[2] The template substrate 7 in the other embodiment of the present disclosure may have a configuration in which the buffer layer 2 is not provided as described above, and may use the seed layer 3 having low reactivity with the main substrate 1, for example. The template substrate 7 not including the buffer layer 2 in the embodiment is as described below. That is, those described above regarding the abnormal portion DP can be understood by appropriately reading the seed layer 3 for the buffer layer 2. For example, the material used as the buffer layer 2 may be used as the material of the seed layer 3, and the abnormal portion DP may be generated in the seed layer 3. In this case as well, in the same or similar manner as discussed above, the template substrate 7, by including the protecting portion PS, can lower the possibility that Ga derived from a Ga raw material and supplied reaches the main substrate 1 when forming the ELO semiconductor layer 8 by the ELO method. As a result, the possibility of the occurrence of the melt-back etching SMB may be lowered, and even if the melt-back etching SMB occurs, the surface area of the region where the melt-back etching SMB occurs may be reduced.

Hereinafter, the template substrate 7 including the buffer layer 2 in the side surface portion SP of the underlying substrate UK will be described as an example. However, as described above, the template substrate 7 may have a configuration not including the buffer layer 2 in the side surface portion SP of the underlying substrate UK. Although not repeatedly described below, it is to be understood that the template substrate 7 in each of Examples may include no buffer layer 2 in the side surface portion SP of the underlying substrate UK unless otherwise specified, and such template substrate 7 is also included in the scope of the present disclosure.

### Example 1

Hereinafter, the template substrate and the like of the present disclosure will be described in more detail with reference to Examples. However, the present disclosure is not limited to each configuration described below, and various modifications can be made within the scope indicated in the claims. Hereinafter, configurations of a plurality of Examples of the present disclosure will be described by assigning the same reference signs to the same or corresponding portions in the drawings. However, unless otherwise specified, forms obtained by appropriately combining the technical methods disclosed in the above-described embodiments and different examples described below are also included in the technical scope of the present disclosure.

### Overall Configuration

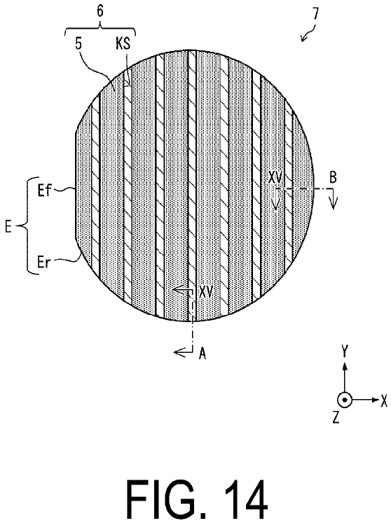

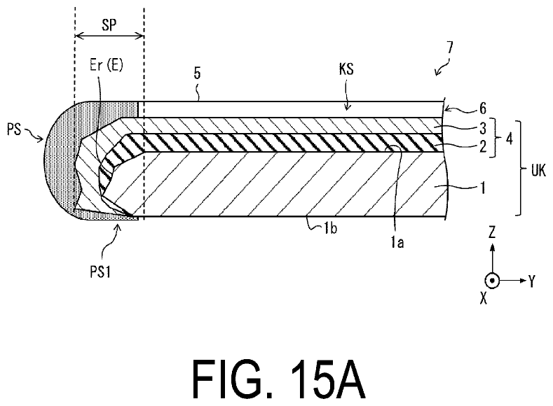

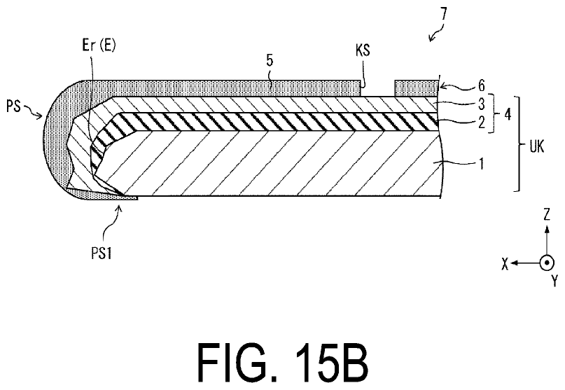

FIG. 14 is a plan view illustrating a configuration of the template substrate 7 in Example 1. FIG. 15A is a cross-sectional view taken along an arrow line A-XV in FIG. 14. FIG. 15B is a cross-sectional view taken along an arrow line B-XV in FIG. 14.

As illustrated in FIGS. 14, 15A, and 15B, the template substrate 7 in Example 1 includes the main substrate 1, the underlying layer 4 and the mask layer 6, and the mask layer 6 includes the mask portion 5 including the protecting portion PS. In the template substrate 7 in Example 1, the protecting portion PS and the mask portion 5 may be integrated with each other.

### Main Substrate

The main substrate 1 is a substrate containing silicon, and may use a substrate made of a material different from a GaN-based semiconductor (heterogeneous substrate). The main substrate 1 may typically be a silicon substrate or may be a silicon-based substrate mainly containing silicon. The main substrate 1 may be, for example, a silicon-based substrate containing silicon at a molar ratio of 90% or more, or may be a silicon-based substrate containing silicon at a molar ratio of 95% or more. The main substrate 1 may be a single crystal substrate or an amorphous substrate. The plane orientation of the main substrate 1 may be, for example, a (111) plane or a (100) plane of the silicon substrate.

The main substrate 1 may be made of a material containing silicon and have a plane orientation, thereby making it possible to grow the ELO semiconductor layer 8 by the ELO method. The main substrate 1 may be a silicon carbide (SiC) substrate, and the SiC substrate has relatively low reactivity with Ga. Because of this, the SiC substrate originally has such a property that the melt-back etching SMB is unlikely to occur therein by nature. Therefore, the main substrate 1 may be a substrate containing silicon excluding a SiC substrate.

In Example 1, the edge E of the main substrate 1 includes the curved surface portion Er and the flat surface portion Ef connected to the curved surface portion Er and having a normal line parallel to the X direction, but the configuration is not limited thereto. The main substrate 1 may have a disc shape. The flat surface portion Ef may have a function as a plane orientation indicator (orientation flat). The plane orientation indicator may be constituted by a notch.

### Underlying Layer

In the template substrate 7, the buffer layer 2 and the seed layer 3 may be provided as the underlying layer 4 in that order from the main substrate 1 side. In Example 1, the buffer layer 2 and the seed layer 3 formed to overlap the entire main surface 1a of the main substrate 1 in a plan view are included.

The buffer layer 2 has, for example, a function of reducing the likelihood of the main substrate 1 and the seed layer 3 coming into contact with each other and melting together. For example, when a silicon substrate is used for the main substrate 1 and a GaN-based semiconductor is used for the seed layer 3, by providing the buffer layer 2 between the silicon substrate and the GaN-based semiconductor, a situation in which the silicon substrate and the GaN-based semiconductor melt together may be reduced. The buffer layer 2 may have an effect of enhancing the crystallinity of the seed layer 3 and/or an effect of relaxing the internal stress of the seed layer 3.

The buffer layer 2 may typically be an AlN layer or a SiC layer. SiC used for the buffer layer 2 may be a hexagonal system (6H-SiC, 4H-SiC) or a cubic system (3C-SiC). The buffer layer 2 may be a multilayer film including an AlN film and/or a SiC film. The buffer layer 2 may include a strain relaxation layer. Examples of the strain relaxation layer include an AlGaN superlattice structure and a graded structure in which the Al composition of AlGaN is changed stepwise. The stress in the longitudinal direction of the ELO semiconductor layer 8 can be relaxed by the strain relaxation layer. The AlN layer being an example of the buffer layer 2 can be formed using an MOCVD device, for example, to have a thickness of from about 10 nm to about 5 μm. The buffer layer 2 may contain a Ga composition of 1% or less. Ga may be inevitably introduced into the buffer layer 2 due to the atomic diffusion of Ga.

The seed layer 3 is a layer serving as a growth starting point of the ELO semiconductor layer 8 when the ELO semiconductor layer 8 is film-formed. For the seed layer 3, a GaN-based semiconductor, aluminum nitride (AlN), silicon carbide (SiC), graphene, or the like may be used. The silicon carbide used for the seed layer 3 is preferably a hexagonal system 6H-SiC or 4H-SiC.

The seed layer 3 may be, for example, an AlGaN layer or a graded layer having an Al composition close to GaN. The graded layer is, for example, a laminate body in which an Al0.7Ga0.3N layer as a first layer and an Al0.3Ga0.7N layer as a second layer are provided in that order from the AlN layer side. In this case, a composition ratio of Ga (0.7/2=0.35) in the second layer (Al:Ga:N=0.3:0.7:1) is larger than a composition ratio of Ga (0.3/2=0.15) in the first layer (Al:Ga:N=0.7:0.3:1). The graded layer may be easily formed by the MOCVD method and may be constituted of three or more layers. By using the graded layer for the seed layer 3, stress from the main substrate 1 as the heterogeneous substrate may be alleviated. The seed layer 3 may be configured to include a GaN layer. In this case, the seed layer 3 may be a GaN single layer, or the uppermost layer of the graded layer as the seed layer 3 may be a GaN layer.

For example, the buffer layer 2 (e.g., aluminum nitride) and/or the seed layer 3 (e.g., GaN-based semiconductor) may be film-formed using a sputtering device (PSD (pulse sputter deposition), PLD (pulse laser deposition), or the like).

The underlying layer 4 may be formed by laminating various layers on the main substrate 1 by using an MOCVD device, a sputtering device, or the like. However, as described above, in general, the buffer layer 2 is not sufficiently formed on the edge E of the main substrate 1. Because of this, the above-described abnormal portion DP may be present in the side surface portion SP of the underlying substrate UK.

### Mask Layer

As the mask layer 6, for example, a single-layer film including any one of a silicon oxide film (SiOx), a titanium nitride film (TiN or the like), a silicon nitride film (SiNx), a silicon oxynitride film (SiON), an aluminum-silicon oxide film (AlSiO), and a metal film having a high melting point (for example, 1000° C. or higher), or a laminate film including at least two thereof may be used.

The opening portion KS has a longitudinal shape, and the plurality of opening portions KS may be periodically arranged with a first period in an a-axis direction (X direction) of the ELO semiconductor layer 8. The width of the opening portion KS may be in a range from about 0.1 μm to about 20 μm. As the width of the opening portion KS is smaller, the number of threading dislocations propagating from the opening portion KS to the ELO semiconductor layer 8 is reduced. The ELO semiconductor layer 8 may be easily peeled in a post process. A surface area of the effective portion EK with few surface defects may be increased.

In Example 1, the mask layer 6 having the mask portion 5 including the protecting portion PS may be formed as follows, for example. First, a silicon oxide film having a thickness in a range from about 100 nm to about 4 μm (preferably from about 150 nm to about 2 μm) is formed on the entire surface of the underlying layer 4 by sputtering. At this time, in Example 1, the silicon oxide film is also formed on the side surface portion SP of the underlying substrate UK. In Example 1, a resist is applied to the entire surface of the silicon oxide film including the silicon oxide film formed on the side surface portion SP of the underlying substrate UK. Subsequently, the resist is patterned by photolithography to form the resist with a plurality of stripe-shaped opening portions. At this time, in Example 1, the resist covering the silicon oxide film formed on the side surface portion SP of the underlying substrate UK is not removed. Thereafter, part of the silicon oxide film is removed by a wet etchant such as hydrofluoric acid (HF), buffered hydrofluoric acid (BHF), or the like to form the mask portion 5 including the plurality of opening portions KS and the protecting portion PS. Then, the resist is removed by organic cleaning to form the mask layer 6.

The mask portion 5 may include the protecting portion PS including the bottom side protecting portion PS1. For example, by using the plasma CVD method, the mask portion 5 is easily formed in such a manner as to extend to the bottom side of the underlying substrate UK.

### Specific Example of Template Substrate

A silicon substrate having a (111) plane was used as the main substrate 1, and the buffer layer 2 of the underlying layer 4 was an AlN layer (for example, 180 nm). The seed layer 3 of the underlying layer 4 was a graded layer in which an Al_{0.6}Ga_{0.4}N layer (for example, 300 nm) as a first layer and a GaN layer (for example, 1 to 2 μm) as a second layer were formed in that order. That is, the composition ratio of Ga (1/2=0.5) in the second layer (Ga:N=1:1) is larger than the composition ratio of Ga (0.6/2=0.3) in the first layer (Al:Ga:N=0.6:0.4:1).

As the mask layer 6, a laminate body in which a silicon oxide film (SiO₂) and a silicon nitride film (SiN) were formed in that order was used. The silicon oxide film had a thickness of, for example, 0.3 μm, and the silicon nitride film had a thickness of, for example, 70 nm. The mask layer 6 was formed to have the mask portion 5 including the protecting portion PS. Each of the silicon oxide film and the silicon nitride film was formed by the plasma CVD method.

### Film Formation of ELO Semiconductor Layer

Although not illustrated, the semiconductor substrate 10 includes the template substrate 7 and the ELO semiconductor layer 8 located above the mask layer 6. The semiconductor substrate means a substrate including a semiconductor layer. The ELO semiconductor layer 8 may be a doped type (for example, an n-type containing a donor or a p-type containing an acceptor) or a non-doped type. Examples of the donor include silicon and germanium, and examples of the acceptor include magnesium. In the case where the ELO semiconductor layer 8 is a doped type, it may contain both the donor and the acceptor.

The ELO semiconductor layer 8 includes a nitride semiconductor, for example. The nitride semiconductor may be expressed, for example, by AlxGayInzN (0≤x≤1; 0≤y≤1; 0≤z≤1; x+y+z=1). Specific examples of the nitride semiconductor may include a GaN-based semiconductor, aluminum nitride (AlN), indium aluminum nitride (InAlN), and indium nitride (InN).

The ELO semiconductor layer 8 was a GaN layer, and ELO film formation was performed on the template substrate 7 of Example 1 by using the MOCVD device. The following may be adopted as examples of the ELO film formation conditions: substrate temperature: 1120° C., growth pressure: 50 kPa, trimethylgallium (TMG): 22 sccm, NH₃: 15 slm, and V/III=6000 (ratio of group V raw material supply amount to group III raw material supply amount). The ELO semiconductor layer 8 selectively grew on the seed layer 3 exposed to the opening portion KS (GaN layer as the uppermost layer of the seed layer 3), and subsequently grew laterally on the mask portion 5. The above lateral growth was stopped before the ELO semiconductor layer 8 growing laterally on the mask portion 5 from both sides thereof met each other.

The width of the mask portion 5 was 50 μm, the width of the opening portion KS was 5 μm, the lateral width of the ELO semiconductor layer 8 was 53 μm, the width (size in the X direction) of the effective portion EK was 24 μm, and the layer thickness of the ELO semiconductor layer 8 was 5 μm. An aspect ratio of the ELO semiconductor layer 8 was 53 μm/5 μm=10.6, and a very high aspect ratio was achieved.

In the formation of the ELO semiconductor layer 8 in Example 1, the lateral film formation rate is increased. A method for increasing the lateral film formation rate is as follows, for example. First, a longitudinal growth layer (initial growth layer SL) to grow in the Z direction (c-axis direction) is formed on the seed layer 3 exposed from the opening portion KS, and then a lateral growth layer to grow in the X direction (a-axis direction) is formed. In this case, by setting the thickness of the longitudinal growth layer to 10 μm or less, preferably 5 μm or less, and more preferably 3 μm or less, the thickness of the lateral growth layer may be suppressed to be thin and the lateral film formation rate may be increased.

As described above, in the semiconductor substrate 10 manufactured by film-forming the ELO semiconductor layer 8 on the template substrate 7 by using the ELO method, the surface area of the region where the melt-back etching SMB occurred was relatively reduced. With the use of the template substrate 7 in Example 1, the possibility of the occurrence of the melt-back etching SMB in the semiconductor substrate 10 was lowered as compared with the case of using the template substrate of related art including no protecting portion PS.

### Example 2

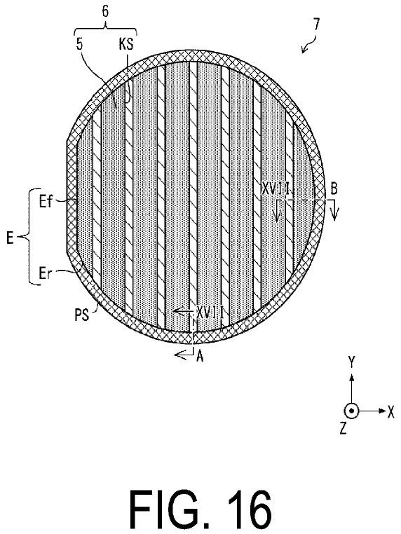

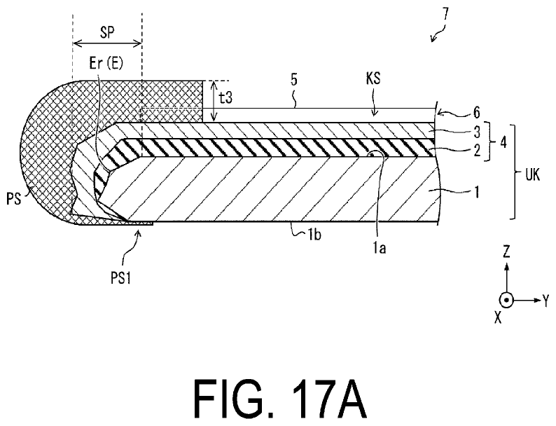

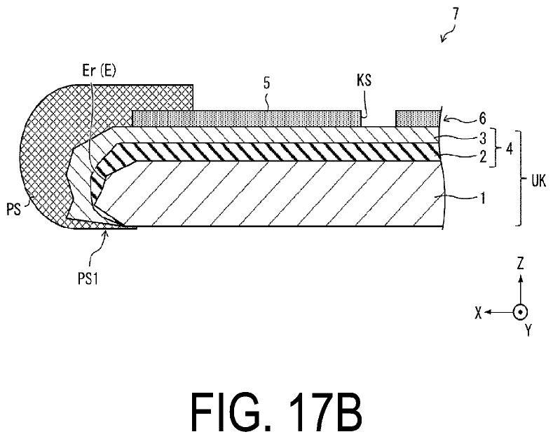

FIG. 16 is a plan view illustrating a configuration of the template substrate 7 in Example 2. FIG. 17A is a cross-sectional view taken along an arrow line A-XVII in FIG. 16. FIG. 17B is a cross-sectional view taken along an arrow line B-XVII in FIG. 16.

In Example 1, the mask layer 6 having the mask portion 5 including the protecting portion PS is formed on the underlying substrate UK, but in Example 2, the protecting portion PS may be provided separate from the mask portion 5. As illustrated in FIGS. 16, 17A, and 17B, the template substrate 7 in Example 2 includes the main substrate 1, the underlying layer 4, the mask layer 6, and the protecting portion PS.

In Example 2, the protecting portion PS may include a material different from that of the mask portion 5. The protecting portion PS may include an inorganic insulating film or an inorganic insulating layer which does not contain Ga or does not substantially contain Ga. The protecting portion PS may be a resin member, a metal member, or a ceramic member which does not contain Ga or does not substantially contain Ga. The protecting portion PS may be made of an appropriate material capable of lowering the possibility of the occurrence of the melt-back etching SMB, and a specific material is not particularly limited.

In Example 2, the protecting portion PS may have a shape that fits to the side surface of the underlying substrate UK, and in this case, the entire outer periphery of the underlying substrate UK may be covered by combining a plurality of protecting portions PS. The protecting portion PS may cover at least part of the mask portion 5 on the upper surface of the underlying substrate UK or may enter at least part of the opening portion KS. That is, the protecting portion PS may overlap the edge E in a side view and may overlap at least part of the main surface 1a in a plan view. The protecting portion PS may cover at least part of the lower surface 1b, that is, may include the bottom side protecting portion PS1.

In Example 2, a thickness t3 of the protecting portion PS may be larger than the thickness of the mask portion 5 in a layer above the main surface 1a. The thickness t3 may be, for example, in a range from 0.05 μm to 3 μm. Thus, the protecting portion PS having a relatively large thickness is present extending from the upper surface of the underlying substrate UK to the side surface portion SP of the underlying substrate UK. Due to this, the thickness of the protecting portion PS covering the side surface portion SP of the underlying substrate UK is easily increased. This makes it possible to easily protect the side surface portion SP of the underlying substrate UK. Thus, the possibility of the occurrence of the melt-back etching SMB may be lowered.

In Example 2, for example, after the mask layer 6 is formed on the underlying substrate UK, the protecting portion PS can be additionally formed on the peripheral edge portion of the underlying substrate UK. Alternatively, the mask layer 6 may be formed after the protecting portion PS is formed on the peripheral edge portion of the underlying substrate UK. The template substrate 7 may be formed by mounting the protecting portion PS formed in advance in such a manner as to cover the peripheral edge portion of the underlying substrate UK. In Example 2, the material, shape, thickness, and the like of the protecting portion PS can be relatively easily adjusted, and the protecting portion PS including the bottom side protecting portion PS1 may also be obtained.

### Example 3

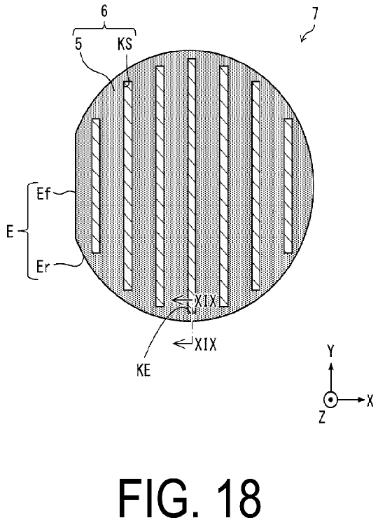

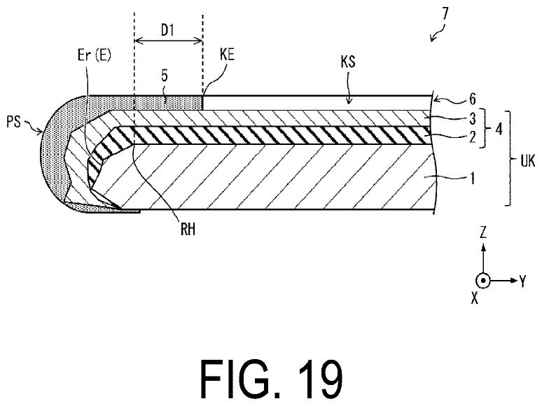

FIG. 18 is a plan view illustrating a configuration of the template substrate 7 in Example 3. FIG. 19 is a cross-sectional view taken along an arrow line XIX-XIX in FIG. 18.

The mask layer 6 having the edge-to-edge shape is provided in Example 1 and Example 2, but the shape thereof is not limited thereto. In Example 3, the mask layer 6 having a shape in which the mask portion 5 is present at both ends in the longitudinal direction of the opening portion KS may be provided.

As illustrated in FIGS. 18 and 19, the template substrate 7 of Example 3 includes the main substrate 1, the underlying layer 4 and the mask layer 6, and the mask layer 6 includes the mask portion 5 including the protecting portion PS. In the mask layer 6, the opening portion KS has a longitudinal shape, and a distance D1 may be secured between a tip KE of the opening portion KS and the edge E of the main substrate 1 (in other words, the position of the ridge line RH discussed above) in a plan view.

In Example 3, the mask layer 6 may be formed by etching the resist while slightly changing the shape of the opening portion at the time of patterning the resist by photolithography in the same or similar method as that in Example 1.

In Example 3, when the ELO semiconductor layer 8 is film-formed on the template substrate 7, the ELO semiconductor layer 8 is as described below in a cross-sectional portion as depicted in FIG. 19, for example. That is, since the tip KE of the opening portion KS is located at a position where the distance D1 is secured, the growth starting point of the ELO semiconductor layer 8 can be set to a position relatively distant from the edge E of the main substrate 1. This makes it possible to lower the possibility that the ELO semiconductor layer 8 is formed to extend to the side of the semiconductor substrate 10. The distance D1 may be 1 μm or more, or may be 1 μm or more and 6000 μm or less. By setting the distance D1 to be 1 μm or more, the possibility that the ELO semiconductor layer 8 is formed to extend to the side of the semiconductor substrate 10 can be further lowered. This makes it difficult for Ga derived from a Ga raw material to be additionally supplied to the side surface portion SP of the underlying substrate UK during the film formation of the ELO semiconductor layer 8. With this, even if a reaction occurs in the abnormal portion DP, the reaction may be limited to a local reaction between the seed layer 3 and the main substrate 1 in the abnormal portion DP. Thus, the possibility of the occurrence of the melt-back etching SMB may be lowered.

### Example 4

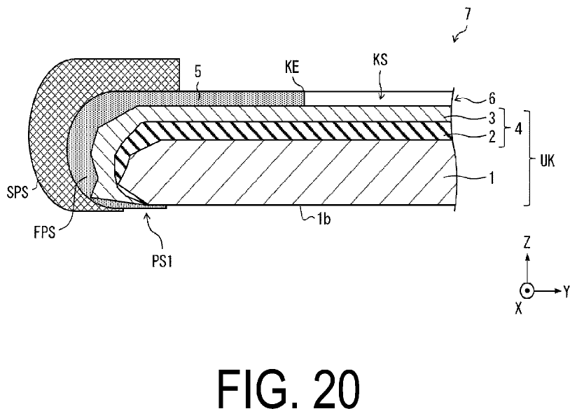

FIG. 20 is a cross-sectional view illustrating a configuration of the template substrate 7 in Example 4.

After the mask layer 6 is formed as in Example 3, the protecting portion PS may be further formed in Example 4. In this case, a first protecting portion FPS and a second protecting portion SPS overlapping the edge E of the main substrate 1 in a side view may be provided.

As illustrated in FIG. 20, in Example 4, the mask layer 6 may include the mask portion 5 including the first protecting portion FPS. That is, the first protecting portion FPS and the mask portion 5 may be integrated with each other. The first protecting portion FPS may be formed to cover the side surface portion SP of the underlying substrate UK. In Example 4, the second protecting portion SPS covering the first protecting portion FPS may be provided. The second protecting portion SPS may include a material different from that of the mask portion 5.

The first protecting portion FPS may be formed in the same or similar manner as that in Example 1 described above, for example. The second protecting portion SPS may be formed in the same or similar manner as the protecting portion PS of Example 2 described above, for example. The first protecting portion FPS may cover at least part of the lower surface 1b of the main substrate 1, that is, may include the bottom side protecting portion PS1. As another example, the second protecting portion SPS may include the bottom side protecting portion PS1. In Example 4, the first protecting portion FPS and/or the second protecting portion SPS may include the bottom side protecting portion PS1.

In Example 4, when the ELO semiconductor layer 8 is film-formed on the template substrate 7, the ELO semiconductor layer 8 is as described below in a cross-sectional portion as depicted in FIG. 20, for example. That is, in Example 4, the side surface portion SP of the underlying substrate UK is protected by both the first protecting portion FPS and the second protecting portion SPS. With this, even in a case where a reaction occurs in the abnormal portion DP described above, a new supply of Ga to the reaction portion can be effectively reduced by the first protecting portion FPS and the second protecting portion SPS. Thus, the reaction may be limited to a local reaction between the seed layer 3 and the main substrate 1 in the abnormal portion DP. As a result, the possibility of the occurrence of the melt-back etching SMB may be largely lowered. Even if the melt-back etching SMB locally occurs, the possibility that the surface area of the region where the melt-back etching SMB occurs increases may be effectively lowered.

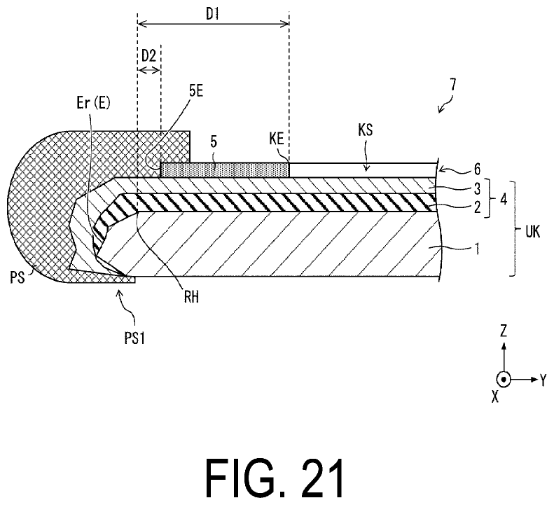

FIG. 21 is a cross-sectional view illustrating another configuration of the template substrate 7 in Example 4. In the other configuration of Example 4, the first protecting portion FPS may not be provided, and the distance D1 may be secured in the mask layer 6. That is, in the other configuration of Example 4, the second protecting portion SPS of Example 4 is replaced with the protecting portion PS as depicted in FIG. 21. In the other configuration of Example 4, in a plan view, a distance D2 may be secured between an end portion 5E of the mask portion 5 on the outer peripheral side of the template substrate 7 and the edge E of the main substrate 1 (in other words, the position of the ridge line RH described above). The distance D2 may be shorter than the distance D1. The distance D2 may be in a range from 1 μm to 3000 μm.

The end portion 5E of the mask portion 5 may be covered with the protecting portion PS. In this case, the seed layer 3 is not exposed in the side surface portion SP of the underlying substrate UK, and the seed layer 3 is not exposed between the side surface portion SP and the end portion 5E. This makes it possible to lower the possibility that Ga is supplied to the abnormal portion DP. As a result, the possibility of the occurrence of the melt-back etching SMB may be lowered.

### Example 5

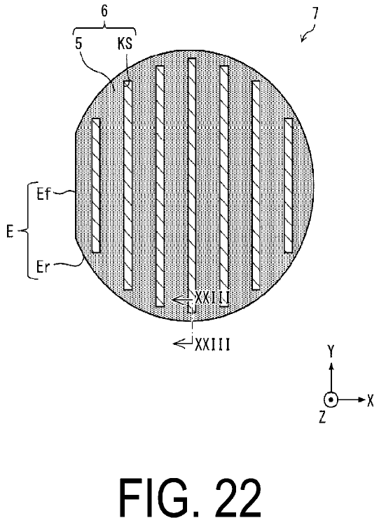

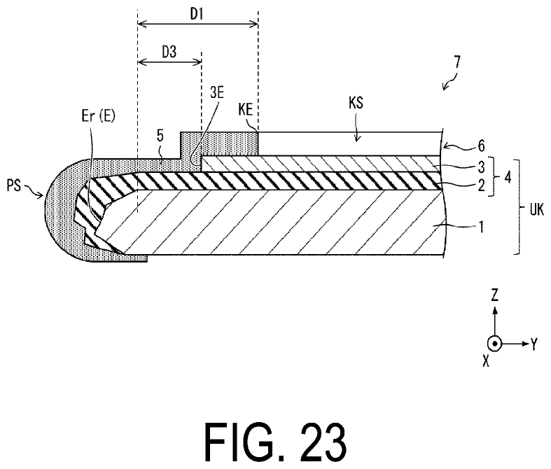

FIG. 22 is a plan view illustrating a configuration of the template substrate 7 in Example 5. FIG. 23 is a cross-sectional view taken along an arrow line XXIII-XXIII in FIG. 22.

In Example 3, the mask portion 5 including the protecting portion PS is formed with the distance D1 secured, and the seed layer 3 overlaps the edge E when viewed from a side. However, the configuration is not limited thereto. In Example 5, the configuration may be such that the seed layer 3 is not present in the side surface portion SP of the underlying substrate UK. Since the seed layer 3 is not present on the side surface of the wafer, the occurrence of the melt-back etching SMB due to non-uniformity of the shape of the side surface of the wafer may be suppressed.

As illustrated in FIGS. 22 and 23, in Example 5, a distance D3 may be secured between an end portion 3E of the seed layer 3 and the edge E of the main substrate 1. The distance D3 may be shorter than the distance D1. The distance D3 may be, for example, in a range from 1 μm to 6000 μm.

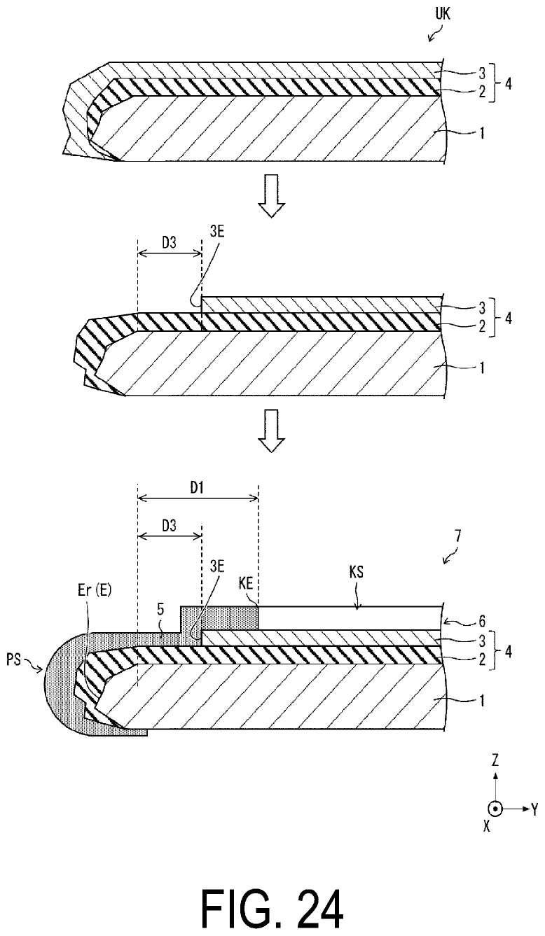

FIG. 24 is a cross-sectional view for explaining a method for manufacturing the template substrate 7 in Example 5. As illustrated in FIG. 24, in Example 5, for example, the underlying substrate UK is prepared first. When the seed layer 3 is formed on the entire surface of the buffer layer 2 of the underlying substrate UK, part of the seed layer 3 is removed by etching or the like to secure the distance D3. Alternatively, after the buffer layer 2 is formed on the main substrate 1, the peripheral portion of the wafer may be masked with a photoresist or a dielectric film such as SiO₂, and then the seed layer 3 may be formed to secure the distance D3 by using a technique such as lift-off. In this way, the underlying substrate UK, from which the seed layer 3 is partially removed, can be obtained.

As the same as or similar to Example 3 discussed above, the mask layer 6 may be formed in such a manner as to secure the distance D1. At this time, the mask layer 6 is formed such that the distance D1 is longer than the distance D3, thereby making it possible to block the generation of an exposed portion of the buffer layer 2.

In Example 5, the seed layer 3 is not present in the side surface portion SP of the underlying substrate UK. Due to this, even if an abnormal portion DP such as a crack or a thinned portion is present in the side surface portion SP of the underlying substrate UK, no factor is present causing a reaction between the seed layer 3 and the main substrate 1 in the abnormal portion DP because the seed layer 3 is not in contact with the abnormal portion DP. The buffer layer 2 is covered with the protecting portion PS in the side surface portion SP of the underlying substrate UK. This makes it difficult for Ga derived from a Ga raw material to be supplied to the abnormal portion DP in the side surface portion SP of the underlying substrate UK during the film formation of the ELO semiconductor layer 8. Thus, the possibility of the occurrence of the melt-back etching SMB may be more effectively lowered.

### Example 6

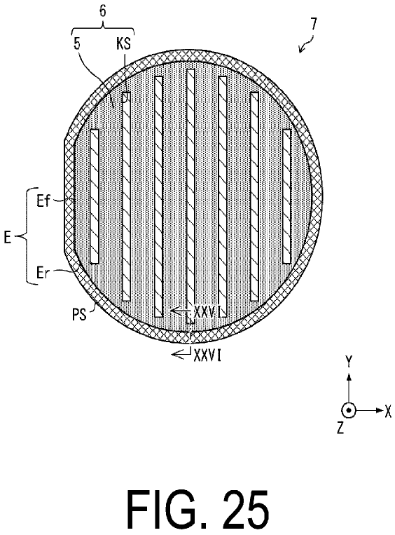

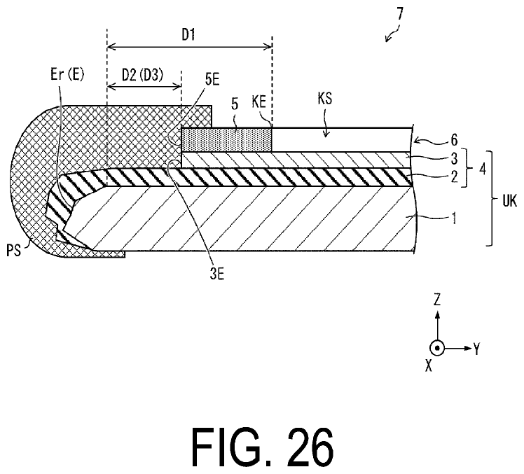

FIG. 25 is a plan view illustrating a configuration of the template substrate 7 in Example 6. FIG. 26 is a cross-sectional view taken along an arrow line XXVI-XXVI in FIG. 25.

The mask layer 6 is formed after removing part of the seed layer 3 in Example 5, but the formation procedure is not limited thereto. In Example 6, after the mask layer 6 is formed on the underlying substrate UK, the seed layer 3 and part of the mask portion 5 may be removed, and the protecting portion PS covering the end portion 5E of the mask portion 5 and the end portion 3E of the seed layer 3 may be provided.

As illustrated in FIGS. 25 and 26, in Example 6, the distance D2 between the end portion 5E of the mask portion 5 on the outer peripheral side of the template substrate 7 and the edge E of the main substrate 1 may be secured, and the distance D3 between the end portion 3E of the seed layer 3 and the edge E of the main substrate 1 may be secured. The distance D2 and the distance D3 may be equal to each other or substantially equal to each other. The distance D2 and the distance D3 may be different from each other.

In Example 6, for example, the underlying substrate UK is prepared first. When the seed layer 3 is formed on the entire surface of the buffer layer 2 of the underlying substrate UK, part of the seed layer 3 is removed by etching or the like to secure the distance D3, and then the mask layer 6 may be formed to secure the distance D2. After the buffer layer 2 is formed on the main substrate 1, the seed layer 3 may be formed to secure the distance D3, and then the mask layer 6 may be formed to secure the distance D2. After the buffer layer 2, the seed layer 3, and the mask layer 6 are formed on the main substrate 1, the seed layer 3 and part of the mask portion 5 may be removed.

Example 6 has the same and/or similar effects as/to those of Example 5 discussed above, and when the ELO semiconductor layer 8 is film-formed on the template substrate 7, the ELO semiconductor layer 8 laterally grown in the Y direction can be formed on the protecting portion PS. That is, the ELO semiconductor layer 8 is not brought into contact with the buffer layer 2. Therefore, in Example 6, the possibility of the occurrence of the melt-back etching SMB may be further lowered.

### Example 7

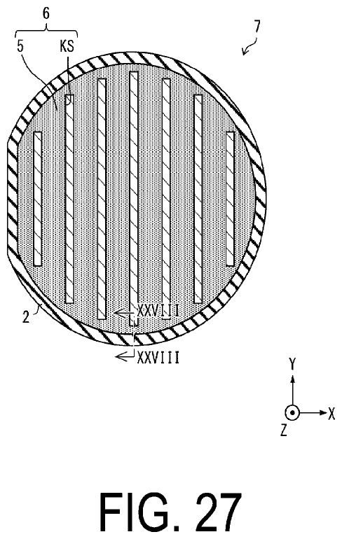

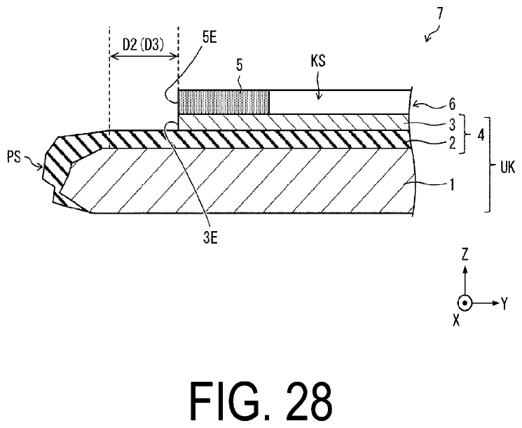

FIG. 27 is a plan view illustrating a configuration of the template substrate 7 in Example 7. FIG. 28 is a cross-sectional view taken along an arrow line XXVIII-XXVIII in FIG. 27.

The protecting portion PS, which is a member different from each layer of the underlying substrate UK, is formed on the outer periphery of the template substrate 7 in Example 6, but is not limited thereto. In Example 7, the protecting portion PS may be included in the buffer layer 2.

As illustrated in FIGS. 27 and 28, in Example 7, the mask layer 6 and the seed layer 3 same as, and/or similar to those of Example 6 described above are provided, and the buffer layer 2 may be used as the protecting portion PS. That is, the buffer layer 2 may include the protecting portion PS, and the buffer layer 2 and the protecting portion PS may be integrated with each other. The buffer layer 2 may include, for example, an aluminum nitride film and/or a silicon carbide film, or may be a multilayer film.

In Example 7 as well, the seed layer 3 is not present in the side surface portion SP of the underlying substrate UK as the same as or similar to Example 5 described above. In the side surface portion SP of the underlying substrate UK, the edge E of the main substrate 1 is covered with the buffer layer 2. Even if an abnormal portion DP such as a crack or a thinned portion is present in the buffer layer 2, the abnormal portion DP is as described below. That is, since the seed layer 3 is not in contact with the abnormal portion DP, no factor causing a reaction between the seed layer 3 and the main substrate 1 in the abnormal portion DP is present. When the ELO semiconductor layer 8 is film-formed on the template substrate 7, Ga derived from a Ga raw material is selectively supplied to the seed layer 3 portion because the buffer layer 2 is made of a material having poor reactivity with Ga. Thus, the possibility that Ga is supplied to the abnormal portion DP to cause the melt-back etching SMB may be lowered.

### Example 8

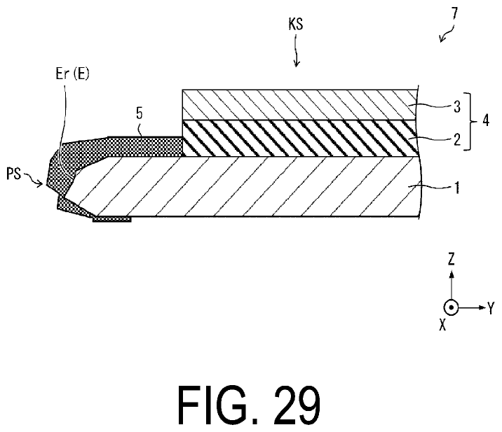

FIG. 29 is a cross-sectional view illustrating a configuration of the template substrate 7 in Example 8.

As illustrated in FIG. 29, in Example 8, the opening portion KS and the mask portion 5 may be formed by performing etching or the like on a surface-treated film formed by thermal oxidation treatment of the main substrate 1 or nitriding treatment of the main substrate 1. Thus, the mask portion 5 including the protecting portion PS can be formed. That is, the mask portion 5 may be constituted of a processing film of the main substrate 1.

In Example 8, for example, first, a substrate processing film (a thermal oxide film or nitrided film) is formed as the mask portion 5 of the mask layer 6 by subjecting the main substrate 1 to thermal oxidation treatment or nitriding treatment. After a resist is applied onto the substrate processing film, the resist is patterned by photolithography to form an opening portion in the resist. The opening portion KS is formed by etching the substrate processing film with an etchant such as hydrofluoric acid. Subsequently, with the resist being left, the underlying layer 4 is film-formed inside the opening portion KS by sputtering or the like. Thus, the template substrate 7 of Example 8 can be manufactured.

In Example 8, the seed layer 3 is not present in the edge E portion of the main substrate 1, and the edge E of the main substrate 1 is covered with the mask portion 5. Thus, the possibility of the occurrence of the melt-back etching SMB may be effectively lowered.

### Example 9

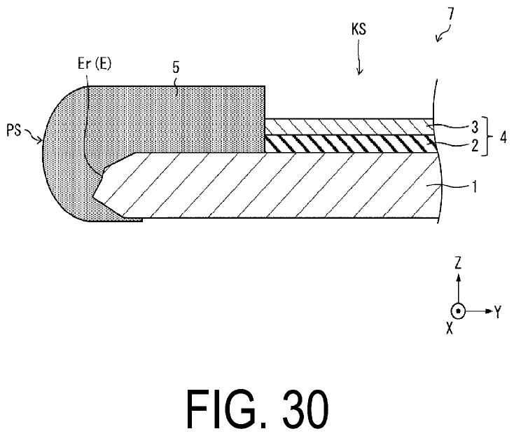

FIG. 30 is a cross-sectional view illustrating a configuration of the template substrate 7 in Example 9.

The mask portion 5, which is a substrate processing film, covering the edge E of the main substrate 1 is provided in Example 8, but is not limited thereto. In Example 9, the mask portion 5 formed by plasma CVD method or the like is provided, and the underlying layer 4 may not be formed on the entire main surface 1a of the main substrate 1.

In Example 9, for example, a silicon oxide film may be formed on the entire main surface 1a of the main substrate 1, and then the opening portion KS may be formed as the same as or similar to Example 8 discussed above. Thereafter, the underlying layer 4 may be formed inside the opening portion KS. In Example 9, the seed layer 3 is not present in the edge E portion of the main substrate 1, and the edge E of the main substrate 1 is covered with the mask portion 5. Thus, the possibility of the occurrence of the melt-back etching SMB may be effectively lowered.

### Example 10

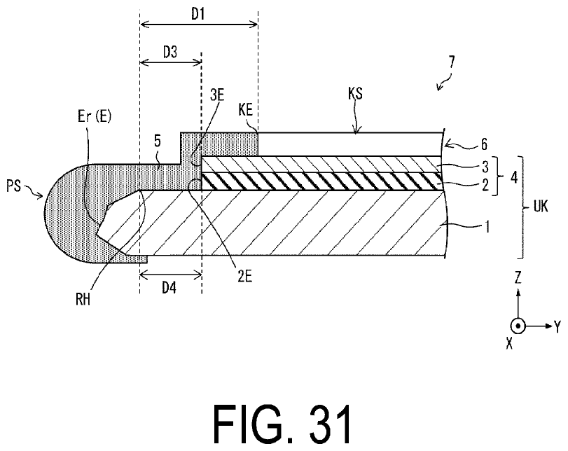

FIG. 31 is a cross-sectional view illustrating a configuration of the template substrate 7 in Example 10.

The configuration in Example 5 is such that the seed layer 3 does not exist in the side surface portion SP of the underlying substrate UK, but is not limited thereto. The configuration of Example 10 may be such that none of the buffer layer 2 and the seed layer 3 are present in the side surface portion SP of the underlying substrate UK, and the mask layer 6 having a shape in which the mask portion 5 is present at both ends in the longitudinal direction of the opening portion KS is provided.

As illustrated in FIG. 31, the template substrate 7 of Example 10 includes the main substrate 1, the underlying layer 4 and the mask layer 6, and the mask layer 6 includes the mask portion 5 including the protecting portion PS. In the mask layer 6, the opening portion KS has a longitudinal shape, and a distance D1 may be secured between a tip KE of the opening portion KS and the edge E of the main substrate 1 (in other words, the position of the ridge line RH discussed above) in a plan view.

In Example 10, the distance D3 may be secured between the end portion 3E of the seed layer 3 and the edge E of the main substrate 1 (see Example 5). A distance D4 may be secured between an end portion 2E of the buffer layer 2 and the edge E of the main substrate 1. The distance D4 may be shorter than the distance D1. The distance D4 may be, for example, in a range from 1 μm to 6000 μm. The distance D3 and the distance D4 may be equal to each other or substantially equal to each other. The distance D3 and the distance D4 may be different from each other.

In Example 10, for example, the underlying substrate UK is prepared first. When the seed layer 3 is formed on the entire surface of the buffer layer 2 of the underlying substrate UK, part of the seed layer 3 may be removed by etching or the like to secure the distance D3. Part of the buffer layer 2 may be removed by etching or the like to secure the distance D4. A specific method is not particularly limited as long as the underlying substrate UK from which the seed layer 3 and the buffer layer 2 are partially removed can be obtained.

As the same as or similar to Example 3 discussed above, the mask layer 6 may be formed in such a manner as to secure the distance D1. At this time, the mask layer 6 is formed such that the distance D1 is longer than the distance D3 and distance D4, thereby making it possible to block the generation of an exposed portion of the main substrate 1.

In Example 10, none of the seed layer 3 and the buffer layer 2 are present in the side surface portion SP of the underlying substrate UK, and the edge E of the main substrate 1 is covered with the protecting portion PS which is part of the mask portion 5. Therefore, the possibility of the presence of the abnormal portion DP in the side surface portion SP of the underlying substrate UK can be lowered, and the possibility that Ga in the atmosphere reaches the main substrate 1 and reacts therewith during the film formation of the ELO semiconductor layer 8 can also be lowered. As a result, the possibility of the occurrence of the melt-back etching SMB may be lowered.

### Example 11

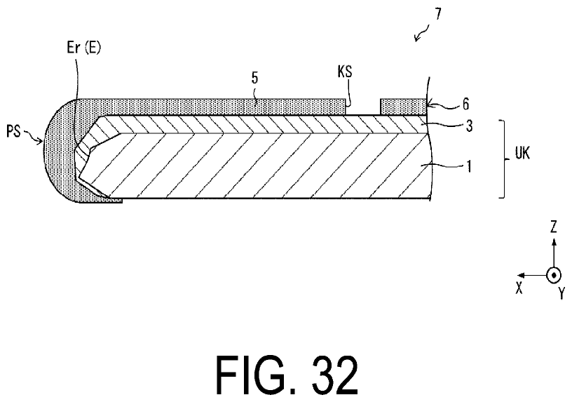

FIG. 32 is a cross-sectional view illustrating a configuration of the template substrate 7 in Example 11.

In Example 1 and the like described above, the underlying substrate UK has a configuration in which the buffer layer 2 and the seed layer 3 are provided as the underlying layer 4 in that order from the main substrate 1 side, but the configuration thereof is not limited thereto. In an example of the present disclosure, the buffer layer 2 may not be provided between the main substrate 1 and the seed layer 3.

As illustrated in FIG. 32, in Example 11, the buffer layer 2 is not provided but the seed layer 3 is provided, and the underlying substrate UK includes the main substrate 1 and the seed layer 3. The mask layer 6 is formed on the underlying substrate UK. The mask layer 6 includes the mask portion 5 including the protecting portion PS. In Example 11, the protecting portion PS and the mask portion 5 may be integrated with each other.

The seed layer 3 may be made of a material having low reactivity with the main substrate 1 and being capable of serving as a growth starting point of the ELO semiconductor layer 8. The seed layer 3 may be, for example, an AlN layer or a SiC layer, or may be a layer containing AlN and/or SiC. The seed layer 3 may be a single-layer film or a multiple-layer film. The seed layer 3 may have a graded structure in which the Al composition changes stepwise in such a manner that a layer on a side closer to the main substrate 1 is an AlN film and a layer on a side farther from the main substrate 1 is a GaN film or an AlGaN film, for example.

In Example 11, if the seed layer 3 is not sufficiently formed on the edge E of the main substrate 1, an abnormal portion DP may be formed in the seed layer 3 in the side surface portion SP of the underlying substrate UK. However, the seed layer 3 can be formed to be a layer that does not contain Ga or does not substantially contain Ga, and the seed layer 3 is covered with the protecting portion PS in the side surface portion SP of the underlying substrate UK. Therefore, the possibility that a reaction between Ga and the main substrate 1 containing silicon occurs in the abnormal portion DP may be lowered. Even if a reaction occurs in the abnormal portion DP in the seed layer 3, a new supply of Ga to the reaction portion is reduced by the protecting portion PS. As a result, the possibility of the occurrence of the melt-back etching SMB may be effectively lowered.

In the above-described various Examples, a configuration not including the buffer layer 2, that is, a configuration in which the buffer layer 2 is not provided between the main substrate 1 and the seed layer 3 may be employed, and such Example is also included in the present disclosure.

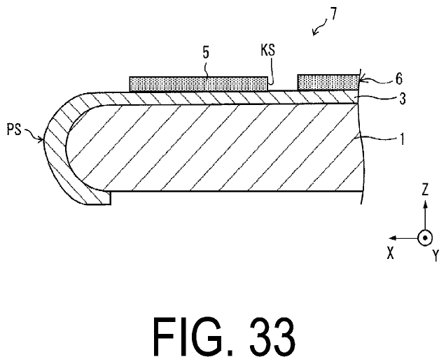

FIG. 33 is a cross-sectional view illustrating another configuration of the template substrate 7 in Example 11. As illustrated in FIG. 33, the seed layer 3 may be located on the main substrate 1, and an end portion of the seed layer 3 (a portion covering a side surface of the main substrate 1) may function as the protecting portion PS. As the seed layer 3 in this case, a single-layer film or a multiple-layer film including AlN and/or SiC can be used. As for the seed layer 3, the thickness of the portion (protecting portion PS) covering the side surface of the main substrate 1 may be equal to or greater than the thickness of the portion covering the upper surface of the main substrate 1, and the seed layer 3 may extend to the lower surface of the main substrate 1.

### Example 12

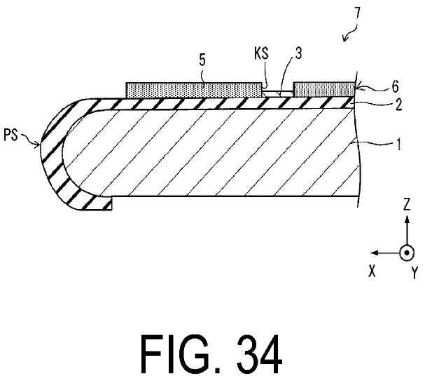

FIG. 34 is a cross-sectional view illustrating a configuration of the template substrate 7 in Example 12. As illustrated in FIG. 34, the buffer layer 2 may be located on the main substrate 1, the seed layer 3 may be locally located on the buffer layer 2 to overlap the opening portion KS of the mask 6, and an end portion of the buffer layer 2 (a portion covering a side surface of the main substrate 1) may function as the protecting portion PS. As the buffer layer 2 in this case, a single-layer film or a multiple-layer film including AlN and/or SiC can be used. As for the buffer layer 2, the thickness of the portion (protecting portion PS) covering the side surface of the main substrate 1 may be equal to or greater than the thickness of the portion covering the upper surface of the main substrate 1, and the buffer layer 2 may extend to the lower surface of the main substrate 1.

### SUPPLEMENTARY NOTE

In the present disclosure, the invention has been described above based on the various drawings and examples. However, the invention according to the present disclosure is not limited to each embodiment described above. For example, an example in which a main substrate containing silicon is used has been described in the above-described examples, and the present disclosure is effective when a main substrate that may possibly cause melt-back etching at the time of forming a semiconductor layer is adopted. An application subject of the present disclosure is not limited to a main substrate containing silicon. As described above, the invention according to the present disclosure can be modified in various ways within the scope illustrated in the present disclosure, and embodiments obtained by appropriately combining the technical methods disclosed in different embodiments are also included in the technical scope of the invention according to the present disclosure. In other words, a person skilled in the art can easily make various variations or modifications based on the present disclosure. Note that these variations or modifications are included within the scope of the present disclosure.

### REFERENCE SIGNS

1 Main substrate
1a Main surface
1b Lower surface
2 Buffer layer (buffer portion)
3 Seed layer (seed portion)
3E, 5E End portion
4 Underlying layer (underlying portion)
5 Mask portion
6 Mask layer (mask)
7 Template substrate
8 ELO semiconductor layer (ELO semiconductor part)
9 Functional layer (functional portion)
10 Semiconductor substrate
20 Semiconductor device
23 Drive substrate
25 Control circuit
30 Electronic device
70 Manufacturing apparatus
71 Mask layer forming unit
72 Protecting portion forming unit
73 Semiconductor layer forming unit
74 Controller
D1, D2, D3, D4 Distance
E Edge (side surface)
Ef Flat surface portion
Er Curved surface portion
KS Opening portion
PS Protecting portion
PS1 Bottom side protecting portion

1. A template substrate comprising:
a main substrate containing silicon and comprising a side surface;
a mask pattern located above the main substrate and comprising an opening portion;
a underlying layer that is located above the main substrate and overlaps the mask pattern; and
a protecting portion overlapping the side surface in a side view and containing a material different from gallium, wherein
the protecting portion and the underlying layer overlap in a plan view.

2.-28. (canceled)

29. The template substrate according to claim 1, wherein
the underlying layer includes a seed layer; and
the protecting portion and the seed layer overlap in a plan view.

30. The template substrate according to claim 1, wherein
the underlying layer includes a seed layer and a buffer layer located between the main substrate and the seed layer; and
the protecting portion and the buffer layer overlap in a plan view.

31. The template substrate according to claim 1, wherein
the protecting portion and the underlying layer overlap in a side view.

32. The template substrate according to claim 1, wherein
an upper surface of the underlying layer contacts with the protecting portion.

33. The template substrate according to claim 1, wherein
the protecting portion comprises a nitride film containing silicon, an oxide film containing silicon, or an oxynitride film containing silicon.

34. The template substrate according to claim 29, wherein
the seed layer comprises a GaN-based semiconductor.

35. The template substrate according to claim 1, wherein
the mask pattern comprises a mask portion comprising the protecting portion.

36. The template substrate according to claim 1, wherein
the mask pattern comprises a mask portion, and
the protecting portion comprises a material different from the mask portion.

37. The template substrate according to claim 1, wherein
the mask pattern comprises a mask portion overlapping the side surface in a side view.

38. The template substrate according to claim 36, wherein
a thickness of the protecting portion is greater than a thickness of the mask portion.

39. The template substrate according to claim 35, wherein
the mask portion is constituted of a processing film of the main substrate.

40. The template substrate according to claim 1, wherein
the opening portion has a longitudinal shape, and
a distance is secured between a tip of the opening portion and the side surface of the main substrate in a plan view seen in a normal direction of the main substrate.

41. The template substrate according to claim 29, wherein
a distance is secured between an edge of the seed layer and the side surface of the main substrate in a plan view seen in a normal direction of the main substrate.

42. The template substrate according to claim 1, wherein
the mask pattern comprises a mask portion,
a distance is secured between an edge of the mask portion and the side surface of the main substrate in a plan view seen in a normal direction of the main substrate, and the protecting portion covers at least part of the edge of the mask portion.

43. The template substrate according to claim 1, wherein
the side surface comprises a curved surface.

44. The template substrate according to claim 1, wherein
the protecting portion is in contact with a lower surface of the main substrate.

45. A semiconductor substrate comprising:
the template substrate according to claim 1; and
a semiconductor part located above the mask pattern.

46. The semiconductor substrate according to claim 45, wherein
the opening portion overlaps the semiconductor part in a plan view seen in a normal direction of the main substrate.

47. A method for manufacturing a template substrate comprising a main substrate containing silicon and comprising a side surface, a mask pattern located above the main substrate and comprising an opening portion, and an underlying layer that is located above the main substrate and overlaps the mask pattern, the method comprising:
forming a protecting portion so as to overlap the underlying layer in a plan view, the protecting portion overlapping the side surface in a side view and containing a material different from gallium.
